(19) United States
(12) Patent Application Publication
(10) Pub. No.: US 2013/0255998 A1
(43) Pub. Date: Oct. 3, 2013

(54) METHOD OF MANUFACTURING CONDUCTIVE SHEET, CONDUCTIVE SHEET, AND RECORDING MEDIUM

(71) Applicant: FUJIFILM Corporation, Tokyo (JP)

(72) Inventors: Kazuchika IWAMI, Ashigarakami-gun (JP); Takashi WAKUI, Ashigarakami-gun (JP); Hideyasu ISHIBASHI, Ashigarakami-gun (JP)

(73) Assignee: FUJIFILM Corporation, Tokyo (JP)

(21) Appl. No.: 13/898,424

(22) Filed: May 20, 2013

Related U.S. Application Data
(63) Continuation of application No. PCT/JP2011/077314, filed on Nov. 28, 2011.

(30) Foreign Application Priority Data
Dec. 1, 2010 (JP) 2010-267951

(51) Int. Cl. H05K 3/10; H05K 1/02

(52) U.S. Cl. CPC H05K 3/10; H05K 1/02
USPC 174/250; 29/850

(57) ABSTRACT

The method of manufacturing a conductive sheet of the present invention is provided with: a creation step for creating image data that indicates a meshed pattern; and an outputting step for outputting and forming wire materials on a base body on the basis of the created image data, and manufacturing a conductive sheet having the meshed pattern. The image data has, in convolution integration of a power spectrum of the image data and standard vision responsiveness of human beings, a characteristic of having each of the integration values at a spatial frequency band that is not less than 1/4 and not more than 1/2 of a Nyquist frequency corresponding to the image data to be greater than integration values at a null-space frequency.

### CROSS-REFERENCE TO RELATED APPLICATIONS AND PRIORITY CLAIM

This application is a Continuation of International Application No. PCT/JP2011/077314 filed on Nov. 28, 2011, which was published under PCT Article 21(2) in Japanese, which is based upon and claims the benefit of priority from Japanese Patent Application No. 2010-267951 filed on Dec. 1, 2010, the contents all of which are incorporated herein by reference.

### TECHNICAL FIELD

The present invention relates to a method of manufacturing a conductive sheet, in which a wire material in the form of a mesh pattern is formed on a substrate, as well as the conductive sheet itself, and a recording medium.

### BACKGROUND ART

Recently, a conductive sheet has been developed, in which a wire material in the form of a mesh pattern is formed on a substrate. The conductive sheet can be used as an electrode or a heat-generating sheet. Not only can the conductive sheet be used as an electrode for a touch panel, or as an electrode for a inorganic EL element, an organic EL element, or a solar cell, but the conductive sheet may also be applied to a defroster (defrosting device), or to an electromagnetic wave shielding element for a vehicle, for example.

To users of the aforementioned various products, depending on the nature of use, cases are known to occur in which such a mesh pattern produces considerable granular noise, which obstructs the visibility of objects to be observed. Various techniques have been proposed in which, by arranging the same or different mesh patterns in a regular or irregular manner, such granular noise is suppressed, whereby the visibility of objects to be observed can be improved.

For example, in Japanese Laid-Open Patent Publication 2009-137455, as shown in FIG. 27A, a window for a riding movable body and the shape of a pattern PT1 thereof in plan view are disclosed, having a mesh layer 4, in which rounded arcuate conductive wires 2 from which portions have been cutout are arranged repeatedly in a lattice shape, and respective ends of the arcuate wires 2 are connected to the vicinity of a center portion of another adjacent arcuate wire 2. In accordance therewith, it is noted that not only visibility but also shielding of electromagnetic waves as well as resistance to breakage can be improved.

Further, as shown in FIG. 27B, according to Japanese Laid-Open Patent Publication No. 2009-016700, a transparent conductive substrate and the shape of a pattern PT2 thereof as viewed in plan are disclosed, which is manufactured using a solution, i.e., a self-organized metal particle solution, which forms a mesh-like structure naturally on the substrate if one side of the substrate is coated and then left untreated. In accordance therewith, it is noted that an irregular-mesh-like structure can be obtained in which moiré phenomena do not occur.

Moreover, as shown in FIG. 27C, according to Japanese Laid-Open Patent Publication No. 2009-302439, a light transmissive electromagnetic shield material and the shape of a pattern PT3 thereof as viewed in plan are disclosed, in which an electromagnetic shield layer 6 has a sea region structure in a sea-island configuration, wherein the shapes of island regions 8 made up from openings surrounded by the electromagnetic shield layer 6 differ mutually from each other. In accordance therewith, it is noted that both optical transparency and electromagnetic shielding are improved without the occurrence of moiré patterns.

However, with the patterns PT1, PT2 disclosed in Japanese Laid-Open Patent Publication No. 2009-137455 and Japanese Laid-Open Patent Publication No. 2009-016700, there are problems with such pattern configurations in relation to further reducing granular noise and improving visibility.

For example, in the mesh pattern PT1 of Japanese Laid-Open Patent Publication No. 2009-137455, since the arcuate wires 2 are repeatedly arranged in a lattice shape, the periodicity of the wires 2 is extremely high. More specifically, if the power spectrum of the pattern PT1 is calculated, it is predicted that the spatial frequency band corresponding to an inverse of the interval at which the wires 2 are arranged has a sharp peak. In this case, for improving visibility of the pattern PT1, the size (diameter) of the arcs must be made small.

Further, with the mesh shaped pattern PT2 of Japanese Laid-Open Patent Publication No. 2009-016700, since the shape and size of the mesh is uneven, the irregularity thereof is extremely high. More specifically, if the power spectrum of the pattern PT2 is calculated, the power spectrum is predicted to be of a substantially constant value irrespective of the spatial frequency band (close to the characteristics of white noise). For further improving visibility of the pattern PT2, the self-organizational size thereof must be made small.

If this is done, however, in either the window for a riding movable body of Japanese Laid-Open Patent Publication No. 2009-137455 or the transparent conductive substrate of Japanese Laid-Open Patent Publication No. 2009-016700, an inconvenience results in that optical transmittance and productivity are reduced for the purpose of improving visibility.

Furthermore, since the pattern PT3 disclosed in Japanese Laid-Open Patent Publication No. 2009-302439 is not configured in a mesh shape, a variance occurs in the wiring shape of the cutting plane. In the case that the pattern PT3 is used as an electrode, for example, an inconvenience results in that a stable power capability cannot be obtained.

### SUMMARY OF INVENTION

The present invention has been made in order to address and solve the aforementioned problems, and has the object of providing a manufacturing method of a conductive sheet having a stable power capability even after being cut, in which by decreasing granular noise caused by the pattern, the visibility of objects to be observed can be improved significantly, and also providing the conductive sheet itself, and a recording medium.

According to the present invention, a method of manufacturing a conductive sheet comprises a generating step of generating image data representing the pattern of a mesh pattern, and an outputting step of outputting and forming a wire material on a substrate based on the generated image data to thereby manufacture the conductive sheet having the mesh pattern, wherein the image data has a characteristic such that, in a convolution integral between a power spectrum of the image data and a standard human visual response characteristic, respective integral values, which reside within a spatial frequency band greater than or equal to 1/4 of and less than or equal to 1/2 of a Nyquist frequency corresponding to the image data, are greater than an integral value thereof at zero spatial frequency.

In a convolution integral between a power spectrum of the image data and a standard human visual response characteristic, respective integral values, which reside within a spatial frequency band greater than or equal to 1/4 of and less than or equal to 1/2 of a Nyquist frequency corresponding to the image data, are greater than an integral value thereof at zero spatial frequency, and therefore, compared to the low spatial frequency band, the noise level in the high special frequency band is relatively large. Although human visual perception has a high response characteristic in a low spatial frequency band, in mid to high spatial frequency bands, properties of the response characteristic decrease rapidly, and thus, the sensation of noise as perceived visually by humans tends to decrease. In accordance with this phenomenon, the sensation of granular noise caused by the pattern of the conductive sheet is capable of being lowered, and the visibility of objects to be observed can be significantly enhanced. Further, the cross sectional shape of the respective wires after cutting is substantially constant, and thus the conductive sheet exhibits a stable conducting capability.

According to the present invention, a method of manufacturing a conductive sheet further comprises a generating step for generating image data representing the pattern of a mesh pattern, based on an evaluation result of superimposed image data obtained by superimposing the mesh pattern on a structural pattern having a pattern different from the pattern of the mesh pattern, and an outputting step of outputting and forming a wire material on a substrate based on the generated image data to thereby manufacture the conductive sheet having the mesh pattern. The superimposed image data has a characteristic such that, in a convolution integral between a power spectrum of the superimposed image data and a standard human visual response characteristic, respective integral values, which reside within a spatial frequency band greater than or equal to 1/4 of and less than or equal to 1/2 of a Nyquist frequency corresponding to the superimposed image data, are greater than an integral value thereof at zero spatial frequency.

By superimposing the structural pattern and generating image data, the mesh pattern can be optimized while taking into consideration the pattern of the structural pattern. Stated otherwise, in observations conducted under a manner of actual use, granular noise is reduced, whereby visibility of objects to be observed can be significantly improved. This is particularly effective in the case that the actual mode of use of the conductive sheet is known.

Further, the structural pattern preferably comprises a black matrix.

Moreover, the method of manufacturing a conductive film may further comprise a cutout step of cutting out, respectively, from a predetermined two-dimensional image region in which the pattern of the mesh pattern is formed, a first image region defining a periodically arranged geometric pattern, and a second image region that includes at least a remaining area of the first image region within the predetermined two-dimensional image region. In the generating step, first image data corresponding to the first image region that was cut out, and second image data corresponding to the second image region that was cut out may be generated, and in the outputting step, by outputting and forming the wire material based on the first image data and the second image data that were generated, the pattern of the mesh pattern may be made up on the substrate. Owing thereto, in the event that a structure is adopted in which plural conductive sheets are stacked, in applications such as touch panels, for example, the occurrence of noise interference (moiré patterns) can be prevented.

Furthermore, the image data preferably includes a plurality of color channels, and the integral value may be a weighted sum of each of the color channels.

Furthermore, the method of manufacturing the conductive sheet may further comprises a selection step of selecting a plurality of positions from within a predetermined two-dimensional image region, wherein, in the generating step, the image data is generated based on the selected plurality of positions.

Furthermore, the standard human visual response characteristic may be obtained based on a Dooley-Shaw function at an observational distance of 300 mm.

A conductive sheet according to the present invention may be manufactured using any of the aforementioned manufacturing methods.

According to the present invention, there is provided a conductive sheet in which a wire material in the form of a mesh pattern is formed on a substrate, wherein, in a convolution integral between a power spectrum as viewed in plan and a standard human visual response characteristic, respective integral values, which reside within a spatial frequency band greater than or equal to 1/4 of and less than or equal to 1/2 of a spatial frequency corresponding to an average line width of the wire material, are greater than an integral value thereof at zero spatial frequency.

According to the present invention, there is provided a conductive sheet in which a wire material in the form of a mesh pattern is formed on a substrate, wherein, under a condition in which a structural pattern having a pattern different from the mesh pattern is superimposed on the conductive sheet, in a convolution integral between a power spectrum as viewed in plan and a standard human visual response characteristic, respective integral values, which reside within a spatial frequency band greater than or equal to 1/4 of and less than or equal to 1/2 of a spatial frequency corresponding to an average line width of the wire material, are greater than an integral value thereof at zero spatial frequency.

A recording medium according to the present invention stores therein a program for creating image data representing the pattern of a mesh pattern, the program enabling the computer to function as an input device for inputting visual information in relation to visibility of a mesh pattern, and an image data generating unit for generating the image data that satisfies predetermined spatial frequency conditions, based on the visual information input from the input device. The predetermined spatial frequency conditions are such that, in a convolution integral between a power spectrum of the image data and a standard human visual response characteristic, respective integral values, which reside within a spatial frequency band greater than or equal to 1/4 of and less than or equal to 1/2 of a Nyquist frequency corresponding to the image data, are greater than an integral value thereof at zero spatial frequency.

In accordance with the conductive sheet manufacturing method, the conductive sheet, and the recording medium according to the present invention, concerning the image data by which a wire material is output and generated on a substrate, in a convolution integral between a power spectrum of the image data and a standard human visual response characteristic, respective integral values, which reside within a spatial frequency band greater than or equal to 1/4 of and less than or equal to 1/2 of a Nyquist frequency corresponding to the image data, are greater than an integral value thereof at zero spatial frequency, and therefore, compared to the low spatial frequency band, the noise level in the high special frequency band is relatively large. Although human visual perception has a high response characteristic in a low spatial frequency band, in mid to high spatial frequency bands, properties of the response characteristic decrease rapidly, and thus, the sensation of noise as perceived visually by humans tends to decrease. In accordance therewith, since the sensation of granular noise caused by the pattern of the conductive sheet is lowered, the visibility of objects to be observed is significantly enhanced. Further, the cross sectional shape of the respective wires after cutting is substantially constant, and thus the conductive sheet exhibits a stable conducting capability.

The aforementioned objects, characteristics, and advantages of the present invention will become more apparent from the following descriptions of preferred embodiments taken in conjunction with the accompanying drawings.

### BRIEF DESCRIPTION OF DRAWINGS

FIG. 1 is an outline schematic block diagram of a manufacturing apparatus for manufacturing a conductive sheet according to an embodiment of the present invention;

FIG. 2A is a partially enlarged plan view of the conductive sheet of FIG. 1;

FIG. 2B is an outline exploded perspective view showing a structural example of a case in which the conductive sheet of FIG. 1 is applied to a touch panel;

FIG. 3 is an outline cross sectional view of the conductive sheet of FIG. 2A;

FIG. 4 is a functional block diagram of a mesh pattern evaluating unit and a data update instructing unit shown in FIG. 1;

FIG. 5 is a view showing a setting screen for setting image data creating conditions;

FIG. 6 is a flowchart providing a description of operations of the manufacturing apparatus of FIG. 1;

FIG. 7A is an outline schematic diagram in which image data representative of a mesh pattern are made visual;

FIG. 7B is a diagram of a two-dimensional power spectrum obtained by implementing a fast Fourier transform on the image data of FIG. 7A;

FIG. 7C is a cross sectional view taken along line VIIC-VIIC of the two-dimensional power spectrum shown in FIG. 7B;

FIG. 8 is a graph of a Dooley-Shaw function (observational distance of 300 mm);

FIG. 9 is an outline explanatory view showing a positional relationship between a two-dimensional power spectrum and a VFT (visual transfer function) shifted toward a high spatial frequency side;

FIG. 10 is a flowchart explaining a method of creating output image data;

FIG. 11 is a graph showing an example of a relationship between seed point arrangement density and total transmittance;

FIGS. 12A and 12B are explanatory diagrams of results using a Voronoi diagram, in which eight regions surrounding eight points are defined;

FIGS. 13A and 13B are explanatory diagrams of results using a Delaunay triangulation method, in which eight triangular regions are defined by respective vertices of eight points;

FIG. 14A is an explanatory diagram showing pixel address definitions in image data;

FIG. 14B is an explanatory diagram showing pixel value definitions in image data;

FIG. 15A is a schematic diagram of initial positions of seed points;

FIG. 15B is a Voronoi diagram formed on the basis of the seed points of FIG. 15A;

FIG. 16 is a detailed flowchart of step S26 shown in FIG. 10;

FIG. 17A is an explanatory drawing showing a positional relationship between first seed points, second seed points, and candidate points within an image region;

FIG. 17B is an explanatory drawing of a result in which the second seed points and the candidate points are exchanged to update the seed point positions;

FIG. 18 is an outline explanatory drawing in which output image data representing an optimized mesh pattern are made visual;

FIG. 19 is a graph illustrating an effect in which standard human visual response characteristics are convoluted with respect to a spectrum of the output image data shown in FIG. 18;

FIG. 20A is an outline explanatory drawing in which first image data are made visual;

FIG. 20B is an outline explanatory drawing in which second image data are made visual;

FIG. 21 is a partially enlarged view of a two-dimensional image region shown in FIG. 20A;

FIG. 22 is a view showing a setting screen for setting image data creating conditions according to a modified example of the present embodiment;

FIG. 23 is a flowchart providing a description of operations of an output image data creating method according to the modified example of the present embodiment;

FIG. 24 is a detailed flowchart of step S27A shown in FIG. 23;

FIG. 25 is an outline explanatory view in which output image data, which are representative of a mesh pattern optimized under conditions of being superimposed with a black matrix, are made visual;

FIG. 26 is an outline cross-sectional view of another example of a conductive sheet; and

FIG. 27A through 27C are enlarged plan views of patterns in accordance with respective comparative examples.

### DESCRIPTION OF EMBODIMENTS

Below, with reference to the accompanying drawings, an explanation shall be given of a preferred embodiment in relation to a manufacturing apparatus for carrying out a conductive sheet manufacturing method according to an embodiment of the present invention.

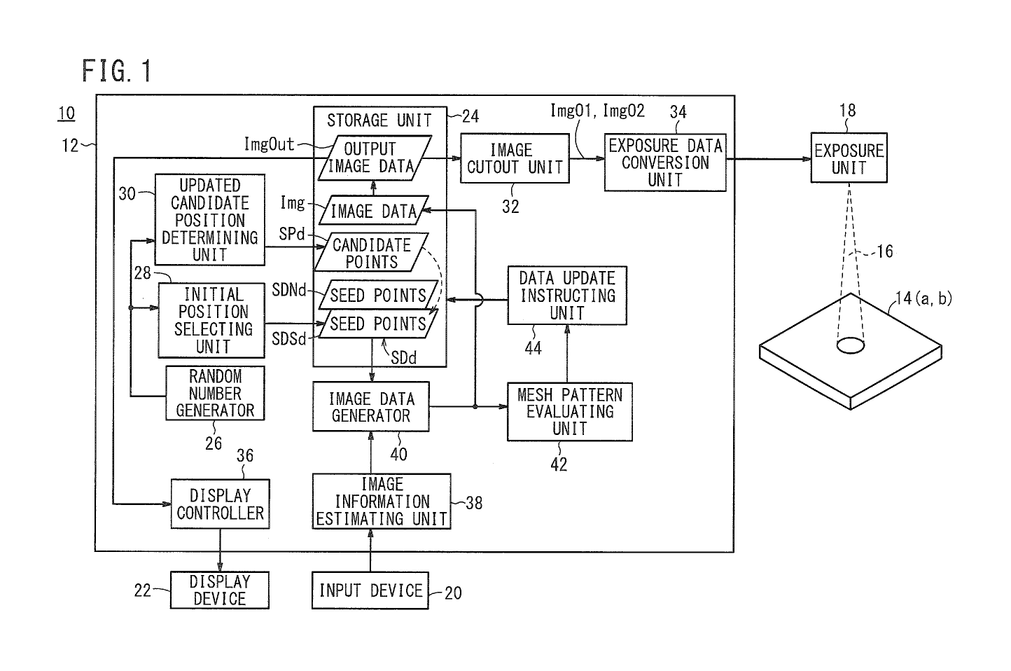

FIG. 1 is an outline schematic block diagram of a manufacturing apparatus 10 for manufacturing a conductive sheet 14 according to the present embodiment.

The manufacturing apparatus 10 basically comprises an image processing device 12 for creating image data Img (including output image data ImgOut) representative of the pattern of a mesh pattern M, an exposure unit 18 for performing exposure by illuminating the conductive sheet 14 with light 16 under a manufacturing process based on the output image data ImgOut created by the image processing device 12, an input device 20 for inputting to the image processing device 12 each of various conditions (including visual information of a mesh pattern M and a later-described structural pattern) for creating the image data Img, and a display device 22 for displaying a GUI image to assist in an input operation by the input device 20, and for displaying stored output image data ImgOut or the like.

The image processing device 12 comprises a storage unit 24 (recording medium), which stores therein image data Img, output image data ImgOut, position data SPd of candidate points SP, and position data SDd of seed points SD, a random number generator 26 for producing a pseudo-random number and generating a random number value, an initial position selecting unit 28 for selecting initial positions of seed points SD from among a predetermined two-dimensional image using the random number value generated by the random number generator 26, an updated candidate position determining unit 30 for determining positions (excluding positions of the seed points SD) of candidate points SP from among the two-dimensional image region using the random number value, an image cutout unit 32 for cutting out first image data ImgO1 and second image data ImgO2 from the output image data ImgOut, an exposure data conversion unit 34 for converting the first image data ImgO1 and the second image data ImgO2 into respective control signals (exposure data) of the exposure unit 18, and a display controller 36 for controlling display of respective images on the display device 22.

The seed points SD are made up from first seed points SDN that are not to be updated, and second seed points SDS that are to be updated. Stated otherwise, the position data SDd of the seed points SD are constituted from position data SDNd of the first seed points SDN and position data SDSd of the second seed points SDS.

The image processing device 12 further comprises an image information estimating unit 38 for estimating image information corresponding to a mesh pattern M or a structural pattern based on visual information (described later) input from the input device 20, an image data generating unit 40 for generating image data Img representative of a pattern corresponding to the mesh pattern M or the structural pattern based on image information supplied from the image information estimating unit 38 and positions of seed points SD supplied from the storage unit 24, a mesh pattern evaluating unit 42 that calculates an evaluation value EVP for evaluating a mesh-shaped pattern based on the image data Img created by the image data generating unit 40, and a data update instructing unit 44 for instructing updating/non-updating of data of seed points SD, evaluation values EVP, etc., based on the evaluation value EVP calculated by the mesh pattern evaluating unit 42.

A non-illustrated controller, which is constituted by a CPU or the like, is capable of implementing all of the controls in relation to image processing. More specifically, such controls include not only control of the various constituent components in the manufacturing apparatus 10 (e.g., reading and writing data of the storage unit 24), but also controlling transmission of display control signals to the display device 22 via the display controller 36, and controlling acquisition of input information via the input device 20.

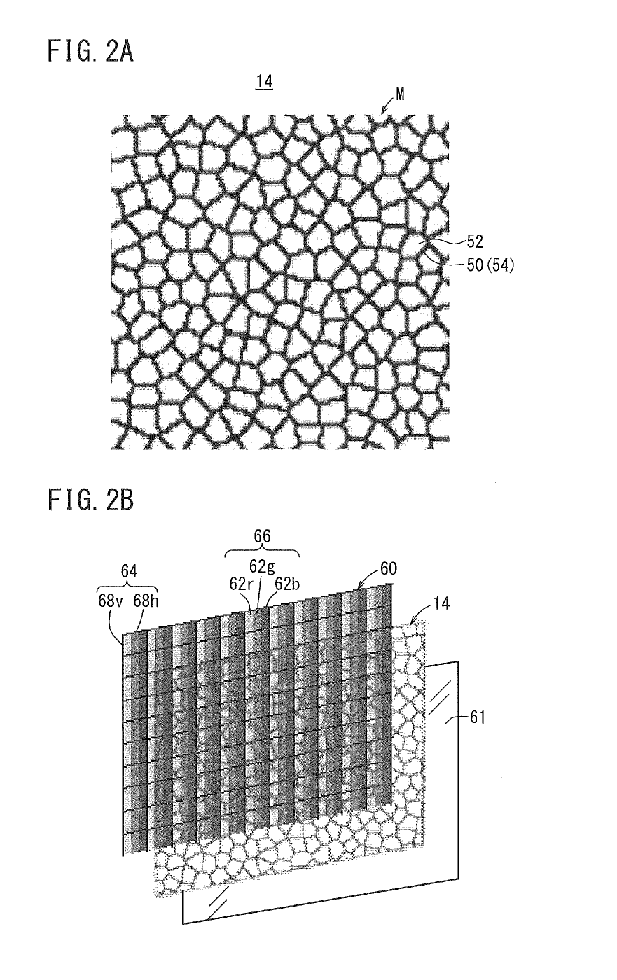

As shown in FIG. 2A, the conductive sheet 14 of FIG. 1 includes a plurality of conductive portions 50 and a plurality of openings 52. The plural conductive portions 50 form a mesh pattern M (mesh-shaped wirings) in which a plurality of metallic thin wires 54 mutually intersect. More specifically, a mesh shape is formed by a combination of one of the openings 52 and at least two conductive portions 50 that surround the one opening 52. In the mesh shape, each of the openings 52 differs from the others, the openings 52 being arrayed irregularly (i.e., aperiodically) respectively. Below, at times, the material constituting the conductive portions 50 will be referred to as a “wire material”.

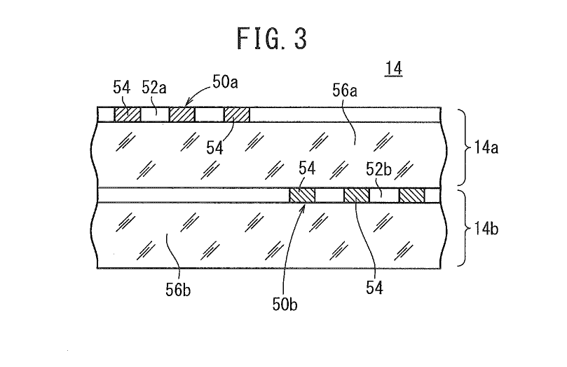

As shown in FIG. 3, the conductive sheet 14 is constituted by stacking a first conductive sheet 14a and a second conductive sheet 14b. The first conductive sheet 14a includes a first transparent substrate 56a (substrate), together with a plurality of first conductive portions 50a and a plurality of first openings 52a, which are formed on the first transparent substrate 56a. Further, the second conductive sheet 14b includes a second transparent substrate 56b (substrate), together with a plurality of second conductive portions 50b and a plurality of second openings 52b, which are formed on the second transparent substrate 56b. By stacking the first conductive sheet 14a and the second conductive sheet 14b, plural conductive portions 50 are formed in which the plurality of first conductive portions 50a and the plurality of second conductive portions 50b are superimposed on each other, and plural openings 52 are formed in which the plurality of first openings 52a and the plurality of second openings 52b are superimposed on each other. Consequently, the pattern of the conductive sheet 14 is formed as a random mesh pattern as viewed in plan.

Apart from being used as an electrode for a touch panel or as an electromagnetic wave shield, the conductive sheet 14 is capable of being used as an electrode for an inorganic EL element, an organic EL element, or a solar cell. An outline exploded perspective view of a case in which the conductive sheet 14 is used as a touch panel electrode is shown in FIG. 2B. A filter member 60 is superimposed on a surface (the front side in the drawing) of the conductive sheet 14, and a protective layer 61 is superimposed on the other surface (the back side in the drawing) thereof. The filter member 60 comprises a plurality of red filters 62r, a plurality of green filters 62g, and a plurality of blue filters 62b, and a black matrix 64 (structural pattern). Below, the material constituting the black matrix 64 may also be referred to as a “pattern material”.

The red filters 62r (the green filters 62g, or the blue filters 62b) are arranged respectively in parallel in a vertical (up/down) direction of the filter member 60. Further, the red filters 62r, the green filters 62g, the blue filters 62b, the red filters 62r, . . . , are arranged in series periodically in a lateral (left/right) direction of the filter member 60. More specifically, a planar region in which one red filter 62r, one green filter 62g, and one blue filter 62b are arranged is constituted as a unit pixel 66 capable of displaying any arbitrary color through a combination of red light emission, green light emission, and blue light emission.

The black matrix 64 has the function of a light-shielding material for preventing mixing of reflective light from the exterior, or transmissive light from a non-illustrated back light at each of the adjacent unit pixels 66. The black matrix 64 is made up from light-shielding materials 68h extending in a horizontal direction, and light-shielding materials 68v extending in a vertical direction. The light-shielding materials 68h, 68v form respective rectangular lattices, each of which surrounds one set of color filters (i.e., the red filter 62r, the green filter 62g, and the blue filter 62b) that constitutes one unit pixel 66.

As techniques for detecting a touch position, preferably, a self-capacitance technique or a mutual capacitance technique can be adopted. Through adoption of such known detection techniques, even if two fingertips simultaneously come into contact with or approach to a surface of a protective layer 61, each of the respective touch positions can be detected. Conventional related detection circuits used in projected capacitive technologies are described in U.S. Pat. Nos. 4,582,955, 4,686,332, 4,733,222, 5,374,787, 5,543,588, and 7,030,860, as well as U.S. Patent Application Publication No. 2004/0155871, etc.

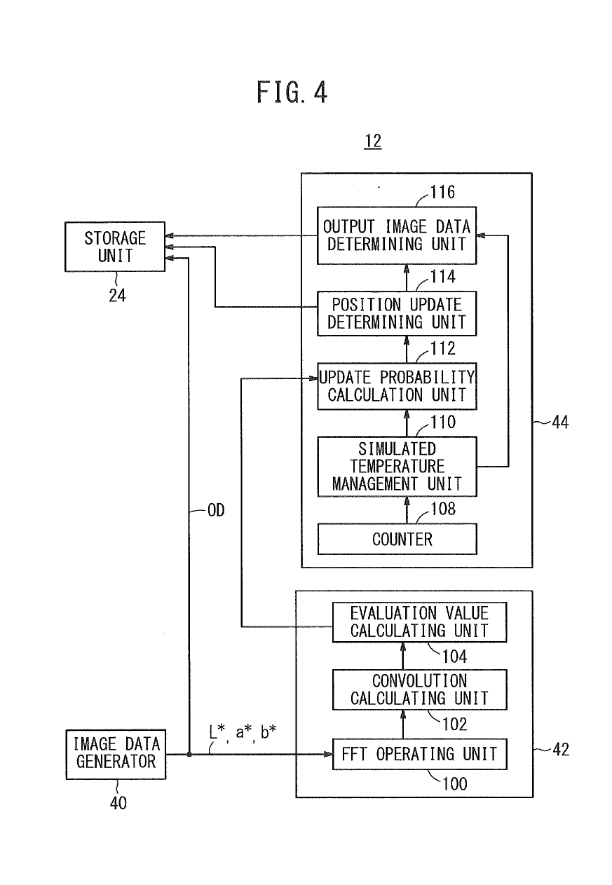

FIG. 4 is a functional block diagram of the mesh pattern evaluating unit 42 and the data update instructing unit 44 shown in FIG. 1.

The mesh pattern evaluating unit 42 comprises an FFT operating unit 100, which carries out fast Fourier transformation (hereinafter also referred to as FFT) on the image data supplied from the image data generating unit 40 to obtain two-dimensional spectral data (hereinafter referred to as a “spectrum Spc”), a convolution calculating unit 102, which obtains a new spectrum Spcc by performing a convolution calculation between the spectrum Spc supplied from the FFT operating unit 100 and a standard human visual response characteristic, and an evaluation value calculating unit 104 for calculating an evaluation value EVP based on the spectrum Spcc supplied from the convolution calculating unit 102.

The data update instructing unit 44 comprises a counter 108 for counting the number of evaluations performed by the mesh pattern evaluating unit 42, a simulated temperature management unit 110 for managing values of simulated temperatures T utilized by a later-described simulated annealing method, and update probability calculation unit 112 for calculating an update probability of the seed points SD based on the evaluation value EVP supplied from the mesh pattern evaluating unit 42 and a simulated temperature T supplied from the simulated temperature management unit 110, a position update determining unit 114 for determining whether to update or not update position data SDd of seed points SD based on the update probability supplied from the update probability calculation unit 112, and an output image data determining unit 116 for determining, as output image data ImgOut, one of the image data Img corresponding to a notification from the simulated temperature management unit 110.

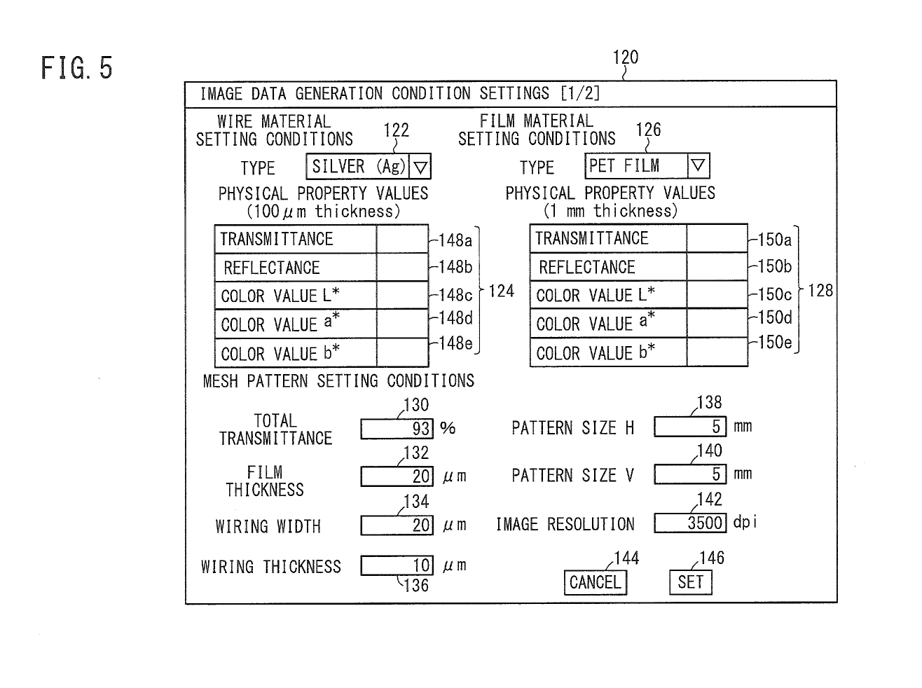

FIG. 5 is a view showing a first setting screen 120 for setting image data generating conditions.

The setting screen 120 comprises, from the top thereof and in the following order, a left side pull down menu 122, a left side display column 124, a right side pull down menu 126, a right side display column 128, seven text boxes 130, 132, 134, 136, 138, 140, 142, and buttons 144, 146 labeled “CANCEL” and “SET” respectively.

To the left of the pull down menus 122 and 126, text is displayed indicating “TYPE”. By operating the input device 20 (e.g., a mouse), non-illustrated selection columns are displayed below the pull down menus 122, 126 to enable the items displayed therein to be selected.

The display column 124 is made up from five respective columns 148a, 148b, 148c, 148d, 148e with text labels “TRANSMITTANCE”, “REFLECTANCE”, “COLOR VALUE L*”, “COLOR VALUE a*” and “COLOR VALUE b*” displayed respectively to the left thereof.

Similar to the display column 124, the display column 128 is made up from five respective columns 150a, 150b, 150c, 150d, 150e with text labels “REFLECTANCE”, “TRANSMITTANCE”, “COLOR VALUE L*”, “COLOR VALUE a*” and “COLOR VALUE b*” displayed respectively to the left thereof.

The label “TOTAL TRANSMITTANCE” is displayed to the left of the text box 130, and “%” is displayed on the right hand side thereof. The label “FILM THICKNESS” is displayed to the left of the text box 132, and “μm” is displayed on the right hand side thereof. The label “WIRING WIDTH” is displayed to the left of the text box 134, and “μm” is displayed on the right hand side thereof. The label “WIRING THICKNESS” is displayed to the left of the text box 136, and “μm” is displayed on the right hand side thereof. The label “PATTERN SIZE H” is displayed to the left of the text box 138, and “mm” is displayed on the right hand side thereof. The label “PATTERN SIZE V” is displayed to the left of the text box 140, and “mm” is displayed on the right hand side thereof. The label “IMAGE RESOLUTION” is displayed to the left of the text box 142, and “dpi” is displayed on the right hand side thereof.

Further, by performing a predetermined operation using the input device 20 (e.g., keyboard), Arabic numerals can be input into any of the seven text boxes 130, 132, 134, 136, 138, 140, 142.

The manufacturing apparatus 10 according to the present embodiment is constructed basically as described above. The image processing functions described above can be performed according to application software (programs) that operate under the control of basic software (an operating system), and which are stored, for example, in the storage unit 24.

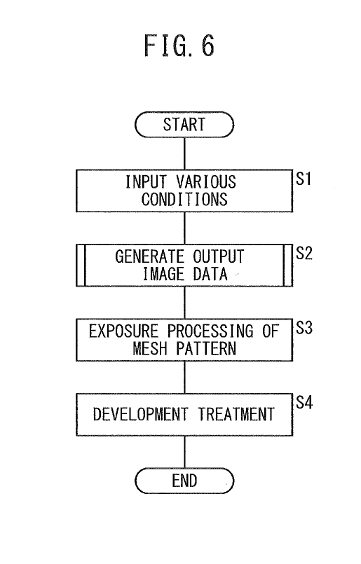

Next, operations of the manufacturing apparatus 10 will be described below with reference to the flowchart of FIG. 6.

First, various conditions necessary for creating the image data Img representing the pattern of the mesh pattern M (including the output image data ImgOut) are input (step S1).

The operator inputs appropriate numerical values, etc., via the setting screen 120 (see FIG. 5) shown on the display device 22. As a result, visual information can be input concerning visibility of the mesh pattern M. Visual information of the mesh pattern M is defined by various information that contribute to the shape and optical density of the mesh pattern M, including visual information of the wire material (metallic thin wire 54), and visual information of the substrate (first transparent substrate 56a, second transparent substrate 56b). As visual information of the wire material, there may be included, for example, at least one of the type, color value, optical transmittance, and optical reflectance of the wire material, and the cross sectional shape and thickness of the metallic thin wire 54. As visual information of the substrate, there may be included, for example, at least one of the type, color value, optical transmittance, optical reflectance, and film thickness of the substrate.

In relation to the conductive sheet 14 to be manufactured, the operator selects one of the types of wire materials using the pull down menu 122. In the example of FIG. 5, “SILVER (Ag)” is selected. Upon selecting one type of wire material, the display column 124 is updated immediately, and predetermined numerical values are newly displayed corresponding to physical properties of the wire material. Values for optical reflectivity (units: %), optical reflectance (unit: %), color value L*, color value a*, color value b* (CIELAB) of silver having a thickness of 100 μm are displayed respectively in the columns 148a, 148b, 148c, 148d, and 148e.

Further, in relation to the conductive sheet 14 to be manufactured, the operator selects one of the types of film materials (first transparent substrate 56a, second transparent substrate 56b) using the pull down menu 126. In the example of FIG. 5, “PET FILM” is selected. Upon selecting one type of film material, the display column 128 is updated immediately, and predetermined numerical values are newly displayed corresponding to physical properties of the film material. Values for optical reflectivity (units: %), optical reflectance (unit: %), color value L*, color value a*, color value b* (CIELAB) of a 1 mm thickness PET film are displayed respectively in the columns 150a, 150b, 150c, 150d, and 150e.

By selecting the item “MANUAL INPUT” (not shown) via the pull down menus 122, 126, various physical property values can be input directly from the display columns 124, 128.

Furthermore, in relation to the conductive sheet 14 to be manufactured, the operator enters various conditions of the mesh pattern M respectively using the text box 130, etc.

The values input to the text boxes 130, 132, 134, 136 correspond respectively to total optical transmittance (units: %), film thickness of the substrate (the total film thickness of the first transparent substrate 56a and the second transparent substrate 56b) (units: μm), line width of the metallic thin wires 54 (units: μm), and thickness of the metallic thin wires 54 (units: μm).

The values input to the text boxes 138, 140, 142 correspond respectively to the horizontal size of the mesh pattern M, the vertical size of the mesh pattern M, and the image resolution (pixel size) of the output image data ImgOut.

After having finished the input operations on the setting screen 120, the operator clicks the “SET” button 146.

Responsive to an operator clicking on the “SET” button 146, the image information estimating unit 38 estimates the image information corresponding to the mesh pattern M. Such image information is referred to at the time that the image data Img (including the output image data ImgOut) is created.

For example, based on the vertical size of the mesh pattern M (the value input to the text box 138) and the image resolution of the output image data ImgOut (the value input to the text box 142), the number of pixels in the vertical direction of the output image data ImgOut can be calculated, and based on the width of the wiring (the value input to the text box 134) and the image resolution, the number of pixels corresponding to the line width of the metallic thin wires 54 can be calculated.

Further, based on the optical transmittance of the wire material (the value displayed in column 148a) and the thickness of the wires (the value input to the text box 136), the optical transmittance of the metallic thin wires 54 themselves can be estimated. In addition thereto, based on the optical transmittance of the film material (the value displayed in the column 150a) and the film thickness (the value input to the text box 132), the optical transmittance under a condition in which the metallic thin wires 54 are laminated on the first transparent substrate 56a and the second transparent substrate 56b can be estimated.

Furthermore, based on the optical transmittance of the wire material (the value displayed in the column 148a), the optical transmittance of the film material (the value displayed in the column 150a), the total transmittance (the value input to the text box 130), and the width of the wires (the value input to the text box 134), the number of openings 52 can be estimated together with estimating the number of seed points SD. The number of seed points SD may also be estimated responsive to an algorithm which determines regions of the openings 52.

Next, output image data ImgOut is generated for creating the mesh pattern M (step S2).

Prior to describing the method of creating output image data ImgOut, a method of evaluating the image data Img will first be described. In the present embodiment, an evaluation is performed based on granular noise characteristics in which a standard human visual response characteristic is taken into consideration.

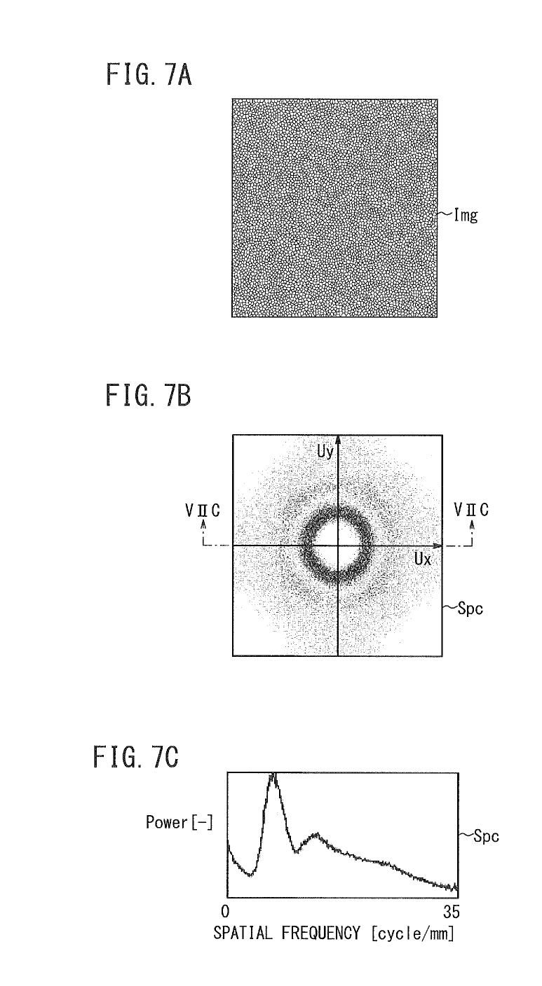

FIG. 7A is an outline schematic diagram in which image data Img representing the pattern of the mesh pattern M are made visual. Below, the image data Img shall be explained by way of example.

First, a fast Fourier transform (hereinafter referred to as “FFT”) is effected on the image data Img shown in FIG. 7A. As a result, concerning the shape of the mesh pattern M, the overall tendency (spatial frequency distribution) thereof can be grasped, rather than a partial shape.

FIG. 7B is a diagram of a spectrum Spc obtained by implementing FFT on the image data Img of FIG. 7A. The horizontal axis of the spectrum diagram indicates the spatial frequency in the X-axis direction, whereas the vertical axis indicates the spatial frequency in the Y-axis direction. Further, as the displayed density within each spatial frequency band becomes thinner, the intensity level (spectral value) becomes smaller, and as the displayed density becomes denser, the intensity level becomes greater. In the example shown in the diagram, the spectral distribution of the spectrum Spc is isotropic having two annular peaks.

FIG. 7C is a cross sectional view taken along line VIIC-VIIC of the spectrum Spc shown in FIG. 7B. Because the spectrum Spc is isotropic, in FIG. 7C, the cross section thereof corresponds to a radial distribution with respect to all angular directions. As understood from the present drawing, the intensity level becomes small in a low spatial frequency band and in a high spatial frequency band, whereas the intensity level is high only in an intermediate spatial frequency band, thereby exhibiting a so-called band-pass characteristic. More specifically, according to common technical terminology in the field of image engineering, the image data Img shown in FIG. 7A is representative of a pattern having a “green noise” characteristic.

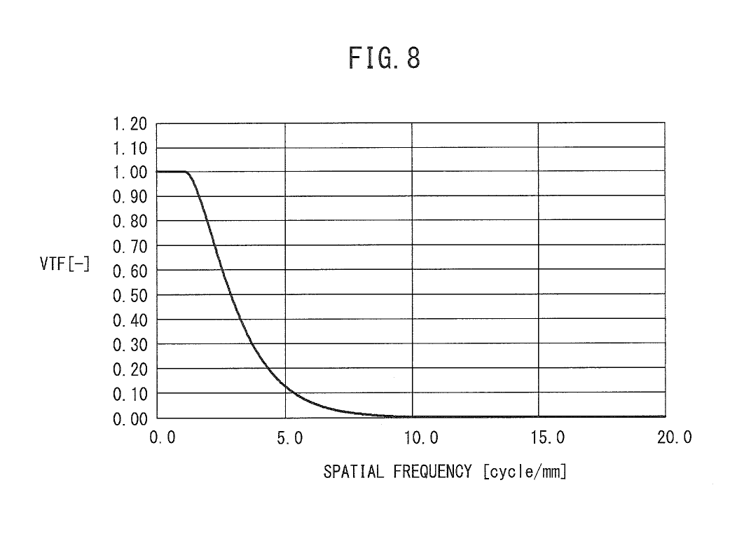

FIG. 8 is a graph of a standard human visual response characteristic.

According to the present embodiment, as the standard human visual response characteristic, a Dooley-Shaw function viewed at an observational distance of 300 mm is used. A Dooley-Shaw function is one type of VTF (Visual Transfer Function), which is a representative function that simulates the standard human visual response characteristic. More specifically, the function corresponds to the square of a luminance contrast ratio characteristic. The horizontal axis on the graph is the spatial frequency (units: cycle/mm), whereas the vertical axis is the value of the VTF (units of which are non-dimensional).

If the observational distance is set at 300 mm, values of the VTF are constant (equivalent to 1) within a range of 0 to 1.0 cycle/mm, and as the spatial frequency grows higher, there is a tendency for the VTF values to decrease. More specifically, the function operates as a low pass filter that blocks or cuts off mid to high spatial frequency bands.

An actual standard human visual response characteristic exhibits the characteristic of a so-called bandpass filter, in which the value thereof becomes smaller than 1 in the vicinity of 0 cycle/mm. However, as exemplified in FIG. 8, in the present embodiment, by setting the VTF value to 1 even in extremely low spatial frequency bands, the contribution to the evaluation value EVP to be described later is high. Consequently, an effect is obtained of suppressing periodicity due to the repeated arrangement of the mesh pattern M.

As viewed from the standpoint of spatial symmetry of the image data Img, the VTF exhibits spatial frequency symmetry {VTF(U)=VTF(−U)}. However, in the present embodiment, spatial frequency characteristics in the negative direction are not taken into account. More specifically, it is assumed that VTF(−U)=0 (where U is a positive value). The same is also true concerning the spectrum Spc.

In the present embodiment, noise intensity NP(Ux, Uy) is defined by the following Formula (1), using the value F(Ux, Uy) of the spectrum Spc.

NP(Ux,Uy)=∫_{Ux}^{Unyq}∫_{Uy}^{Unyq}VTF(\sqrt{(Wx−Ux)²+(Wy−Uy)²})F(Wx,Wy)dWxdWy (1)

Stated otherwise, the noise intensity NP(Ux, Uy) corresponds to a convolution integral (function of Ux, Uy) between the power spectrum (Spc) and the standard human visual response characteristic (VTF). For example, in relation to spatial frequency bands in excess of the Nyquist frequency Unyq, normally, the convolution integral is calculated as F(Ux, Uy)=0. Below, in certain cases, the noise intensity NP(Ux, Uy) will be referred to as a new spectrum Spcc.

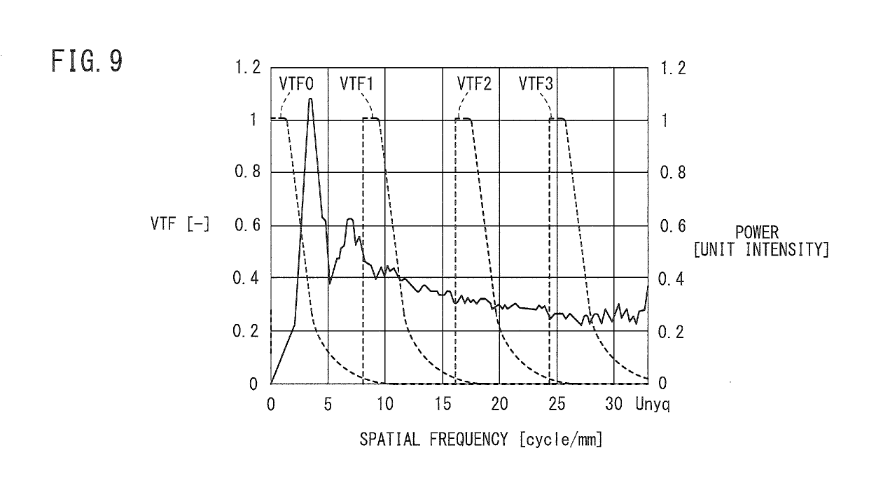

FIG. 9 is an outline explanatory view showing a positional relationship between the spectrum Spc and the VFT, which is shifted toward a high spatial frequency side. The amount by which the VTF is shifted corresponds to U=(Ux²+Uy²)^{1/2} (units: cycle/mm) in Formula (1). The curves VTF0, VTF1, VTF2, and VTF3 shown by the broken lines in FIG. 9 correspond to VTF values of 0, Unyq/4, Unyq/2, and 3·Unyq/4, respectively.

In addition, an evaluation value EVP is defined by the following Formula (2).

$$EVP = {\sum }_{j = 1}^{3} Aj {\int }_{0}^{2 π} Θ ( NP ( 0 , 0 ) - NP ( \frac{j}{4} Unyq cos φ , \frac{j}{4} Unyq sin φ ) ) d φ \qquad ( 2 )$$

Aj (where j=1 to 3) is an arbitrary coefficient (non-negative real number) determined beforehand. Further, Θ(x) is a step function, in which Θ(x)=1 in the case that x>0, and Θ(x)=0 in the case that x≦0. Furthermore, Unyq represents the Nyquist frequency of the image data Img. For example, in the event that resolution of the image data Img is 1750 dpi (dots per inch), the Nyquist frequency corresponds to Unyq=34.4 cycle/mm. Moreover, the variable φ is an angular parameter (0≦φ≦2π) on the Ux−Uy plane.

As understood from formula (2), in the case that respective noise intensities NP(Ux, Uy), which reside within spatial frequencies higher than 1/4 the frequency of the Nyquist frequency Unyq, are greater than the noise intensity NP(0, 0) at zero spatial frequency, the right-side value becomes zero. The evaluation value EVP becomes minimal in the event that this condition (predetermined spatial frequency condition) is satisfied. As the evaluation value EVP goes lower, the spectrum Spc exhibited by the pattern of the mesh pattern M is suppressed in the low spatial frequency domain. More specifically, the granular noise characteristic exhibited by the mesh pattern M approaches a so-called “blue noise” region, in which the noise intensity NP(Ux, Uy) is eccentrically located on the side of the high spatial frequency band. Owing thereto, a mesh pattern can be obtained in which graininess is not noticeable to human visual perception under conditions of normal observation.

It goes without saying the formula for computing the evaluation value EVP may be modified in various ways, responsive to the evaluation function and the target level (acceptable range or tolerance) for determining the mesh pattern M.

Below, a detailed method for determining output image data ImgOut based on the above-described evaluation value EVP shall be explained. For example, a method can be used in which generation of image data Img for different patterns, and evaluation thereof by the evaluation value EVP are repeated successively. In this case, as an optimization problem for determining the output image data ImgOut, various search algorithms can be used, such as a constructive algorithm or an iterative improvement algorithm, etc.

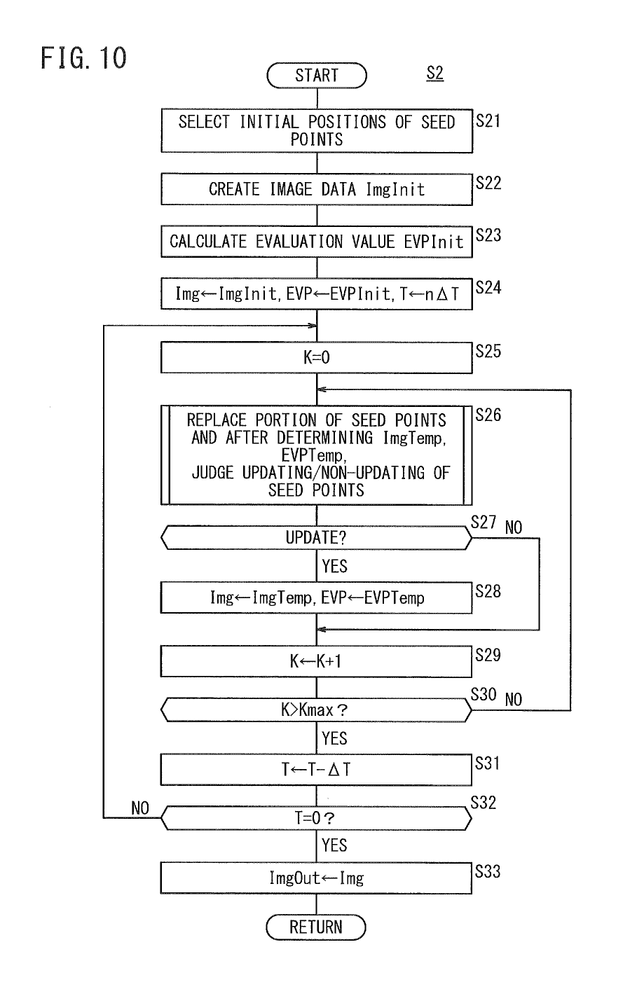

Primarily with reference to the flowchart of FIG. 10 and the functional block diagram of FIG. 1, explanations shall be given concerning an optimization method for optimizing the mesh pattern M by means of a simulated annealing method (hereinafter referred to as an SA method) according to the present embodiment. The SA method is a stochastic search algorithm modeled on an “annealing method” for obtaining robust iron by striking iron in a high temperature condition.

First, the initial position selecting unit 28 selects initial positions of seed points SD (step S21).

Prior to selecting the initial positions, the random number generator 26 generates a random number value using a pseudo-random number generating algorithm. As one such pseudo-random number generating algorithm, any of various algorithms may be used, such as a Mersenne Twister, an SIMD-Oriented Fast Mersenne Twister (SFMT), or an Xorshift method. Then, using the random number value supplied from the random number generator 26, the initial position selecting unit 28 determines initial positions of the seed points SD in a random fashion. The initial position selecting unit 28 selects initial positions of the seed points SD as pixel addresses in the image data Img, and the seed points SD are set at respective positions that do not overlap one another.

Based on the number of pixels in vertical and horizontal directions of the image data Img supplied from the image information estimating unit 38, the initial position selecting unit 28 determines beforehand the range of the two-dimensional image region. Further, the initial position selecting unit 28 acquires beforehand from the image information estimating unit 38 the number of seed points SD, and based thereon, the number of seed points SD is determined.

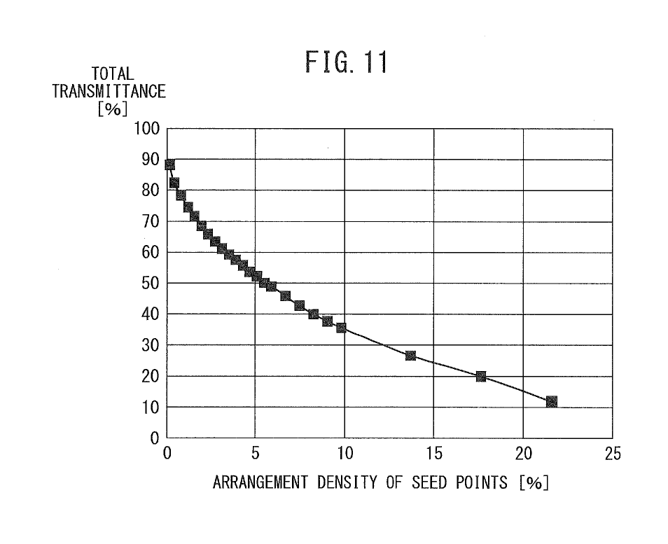

FIG. 11 is a graph showing an example of a relationship between an arrangement density of seed points SD and the total transmittance of the mesh pattern M. In the illustrated graph, it is shown that as the arrangement density becomes higher, the coverage area of the wires increases, and as a result, the total transmittance of the mesh pattern decreases.

The graph characteristics exhibit changes responsive to the optical transmittance of the film material (as indicated in the column 150a of FIG. 5), the wiring width (the value input to the text box 134 of FIG. 5), and a region determining algorithm (e.g., a Voronoi diagram). Thus, characteristic data responsive to each of the parameters such as wiring width or the like may be stored beforehand in the storage unit 24, in any of various data formats consisting of functions, tables, or the like.

Further, a correspondence between the arrangement density of the seed points SD and an electrical resistance value of the mesh pattern M may be acquired beforehand, whereby the number of seed points SD may be determined based on a specified electrical resistance value. The electrical resistance value is one parameter indicative of electrical conductivity of the conductive portions 50, which is essential to the design of the mesh pattern M.

The initial position selecting unit 28 may also select the initial positions of the seed points SD without using a random number value. For example, the initial positions can be determined by referring to data acquired from an external apparatus including a non-illustrated scanner or storage device. Such data, for example, may be predetermined binary data, and more specifically, may be halftone data used for printing.

Next, the image data generating unit 40 generates image data ImgInit that serves as initial data (step S22). The image data generating unit 40 generates image data ImgInit (initial data) representing the pattern corresponding to the mesh pattern M, based on the number of seed points SD and the position data SDd supplied from the storage unit 24, along with image information supplied from the image information estimating unit 38.

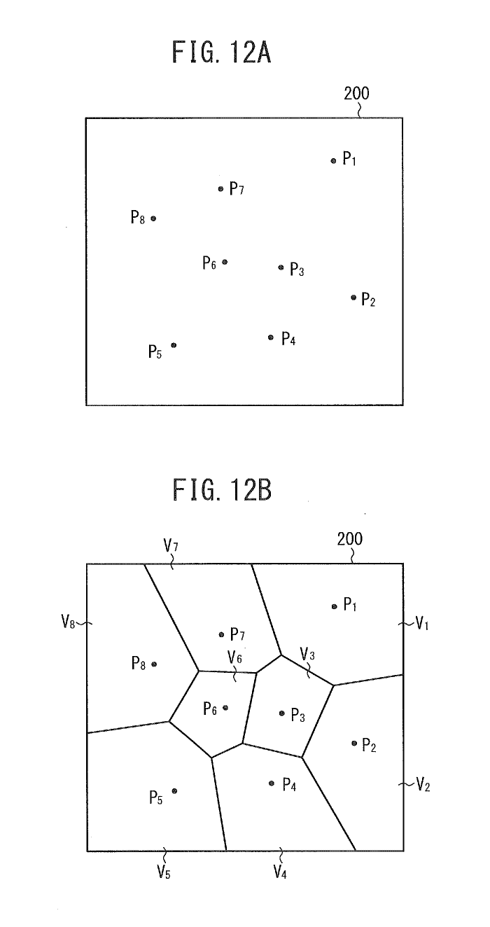

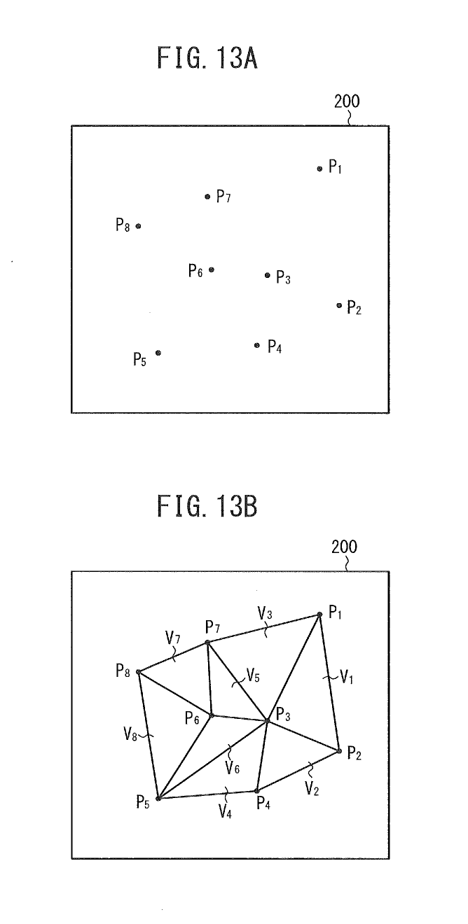

A variety of methods may be adopted as the algorithm for determining a mesh-shaped pattern from multiple seed points SD. Below, explanations shall be given in detail with reference to FIGS. 12A through 13B.

As shown in FIG. 12A, for example, it is assumed that eight points P₁ to P₈ are selected at random from within a rectangular two-dimensional image region 200.

FIG. 12B is an explanatory diagram of results using a Voronoi diagram, in which eight regions V₁ through V₈ surrounding eight points P₁ to P₈ respectively are defined. Euclidean distance is used as a distance function. As can be understood from the drawing, with respect to the arbitrary points from within the regions Vᵢ (where i=1 to 8), the point Pᵢ is shown to be the closest point of the points P. Consequently, the regions Vᵢ are defined in polygonal shapes, respectively.

Further, in FIG. 13B, a result is shown in which eight triangular regions are defined by respective vertices of the points P₁ to P₈ of FIG. 13A (which is the same as FIG. 12A) using a Delaunay triangulation method.

Delaunay triangulation is a method of defining triangular shapes by connecting adjacent points from among the points P₁ to P₈. According to this method as well, regions V₁ to V₈ can be determined in the same number as the number of points P₁ to P₈. In this case, the regions Vᵢ are defined in triangular shapes, respectively.

Incidentally, prior to generating the image data Img (including the initial image data ImgInit), definitions of pixel addresses and pixel values therefor are determined beforehand.

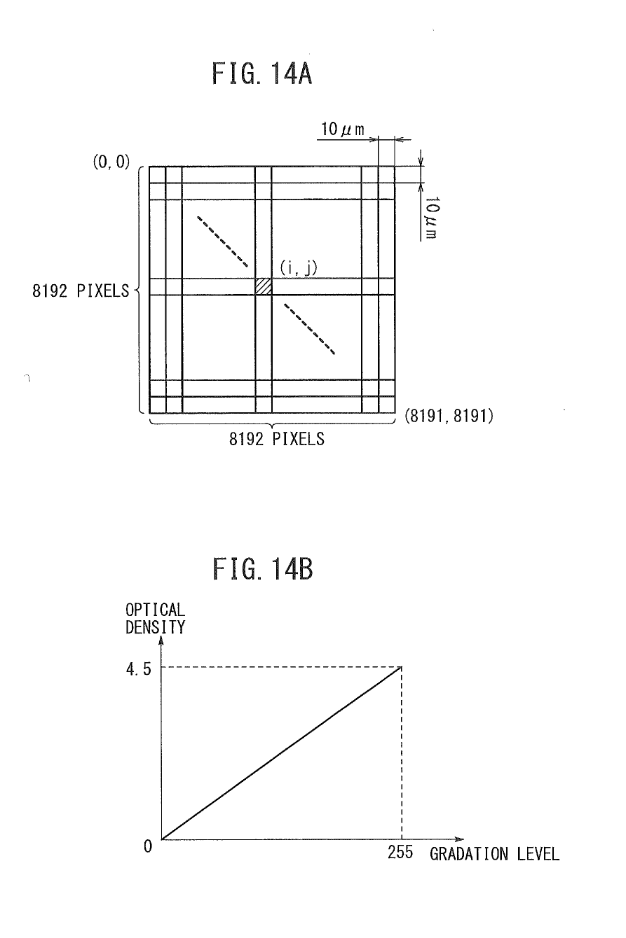

FIG. 14A is an explanatory diagram showing image pixel address definitions in the image data Img. For example, it is assumed that the pixel size is 10 μm, and the number of pixels in both vertical and horizontal directions of the image data is 8192 pixels respectively. For facilitating the FFT calculation process, to be described later, the number of pixels may be set as a power of 2 (e.g., 2 to the 13th power). At this time, the entire image region of the image data Img corresponds to a rectangular region of roughly 82 mm square.

FIG. 14B is an explanatory diagram representing pixel value definitions in the image data Img. For example, it is assumed that the number of gradation levels for each individual pixel is 8 bits (256 gradations). An optical density of zero is set to correspond to a pixel value of zero (lowest value), whereas an optical density of 4.5 is set to correspond to a pixel value of 255 (highest value). For pixel values 1 to 254 therebetween, values are determined according to a linear relationship with respect to the optical density. It goes without saying that the optical density is not limited solely to transmissive density, but may be also reflective density, and can be selected appropriately depending on the manner in which the conductive sheet 14 is to be used. Further, apart from optical density, tristimulus values XYZ, RGB color values, or L*a*b* color values, etc., can also be used to define respective pixel values, similar to the above description.

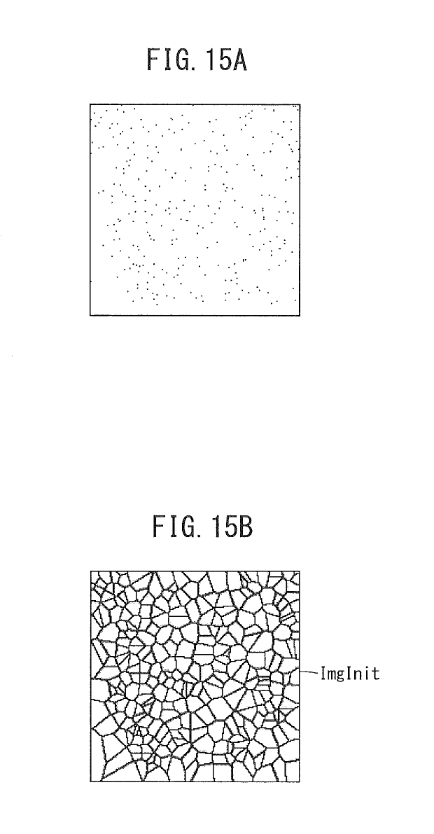

In this manner, the image data generating unit 40 creates the initial image data ImgInit representing the mesh pattern M, based on the data definition of the image data Img and the image information estimated by the image information estimating unit 38 (refer to the description of step S1) (step S22). Using a Voronoi diagram as a reference for the initial positions of the seed points SD (see FIG. 15A), the image data generating unit 40 determines initial conditions for the mesh pattern M shown in FIG. 15B. Concerning the end portions of the image, processing is performed so as to repeatedly arrange the same in vertical and horizontal directions. For example, concerning seed points SD in the vicinity of the left end (or right end) of the image, processing is performed such that regions V, are obtained between such left-end (or right-end) seed points SD and other seed points SD in the vicinity of the right end (or left end) of the image. Similarly, concerning seed points SD in the vicinity of the upper end (or lower end) of the image, processing is performed such that regions Vᵢ are obtained between such upper-end (or lower-end) seed points SD and other seed points SD in the vicinity of the lower end (or upper end) of the image.

Below, the image data Img (including the image data ImgInit) is handled as respective 4-channel image data made up of optical density OD, color value L*, color value a*, and color value b*.

Next, the mesh pattern evaluating unit 42 calculates the evaluation value EVPInit (step S23). In the SA method, the evaluation value EVP assumes the role of a cost function.

More specifically, the FFT operating unit 100 shown in FIG. 4 effects FFT with respect to the image data ImgInit. In addition, the convolution calculating unit 102 convolutes the standard human visual response characteristic (see FIG. 8) with respect to the spectrum Spc supplied from the FFT operating unit 100, and calculates a new spectrum Spcc. In addition, the evaluation value calculating unit 104 calculates the evaluation value EVP based on the new spectrum Spcc supplied from the convolution calculating unit 102.

From within the image data Img, evaluation values EVP(L*), EVP(a*), EVP(b*) are calculated respectively for each of the respective channels for the color value L*, the color value a*, and the color value b* (refer to formula (2) above). In addition, the evaluation value EVP is obtained by a product-sum operation using a predetermined weighting coefficient.

In place of the color values L*, a*, b*, optical density OD may also be used. In relation to the evaluation value EVP, depending on the type of observational mode, i.e., corresponding to whether the auxiliary light source is predominantly transmissive light, predominantly reflective light, or a mixture of transmissive and reflective light, an appropriate calculation method can be selected that complies with human visual sensitivity.

Further, it goes without saying that the formula for computing the evaluation value EVP may be changed corresponding to the target level (acceptable range or tolerance) or the evaluation function for determining the mesh pattern M.

In this manner, the mesh pattern evaluating unit 42 calculates the evaluation value EVPInit (step S23).

Next, the storage unit 24 temporarily stores the image data ImgInit created in step S22, and the evaluation value EVPInit calculated in step S23 (step S24). Along therewith, an initial value nΔT (where n is a natural number and ΔT is a positive real number) is assigned to the simulated temperature T.

Next, the counter 108 initializes the variable K (step S25). That is, the counter 108 assigns 0 to the variable K.

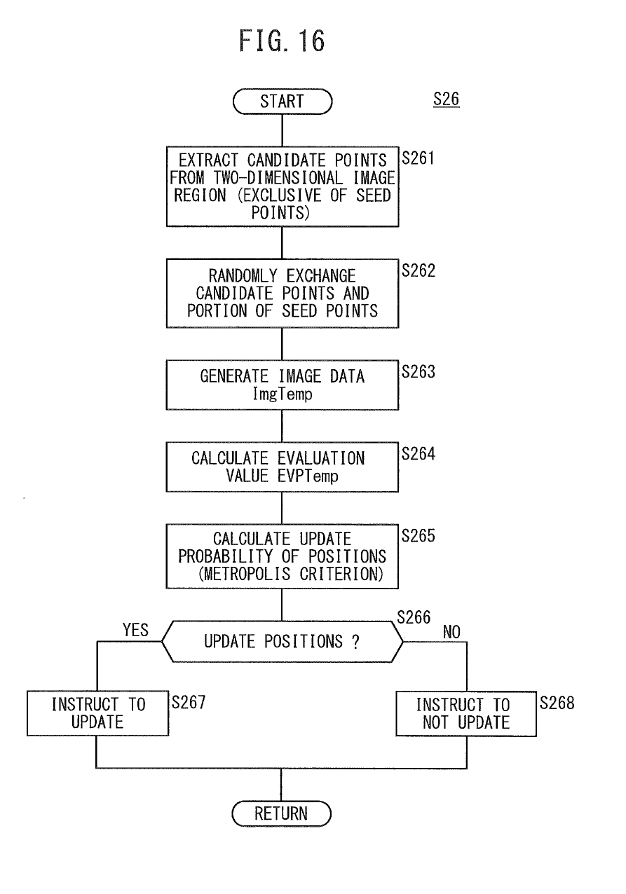

Then, in a state in which a portion of the seed points SD (second seed points SDS) are replaced by candidate points SP, and after image data ImgTemp is created and the evaluation value EVPTemp is calculated, a determination is made as to whether to “update” or “not update” the seed points SD (step S26). Further details concerning step S26 will be described with reference to the flowchart of FIG. 16 and the functional block diagrams of FIG. 1 and FIG. 4.

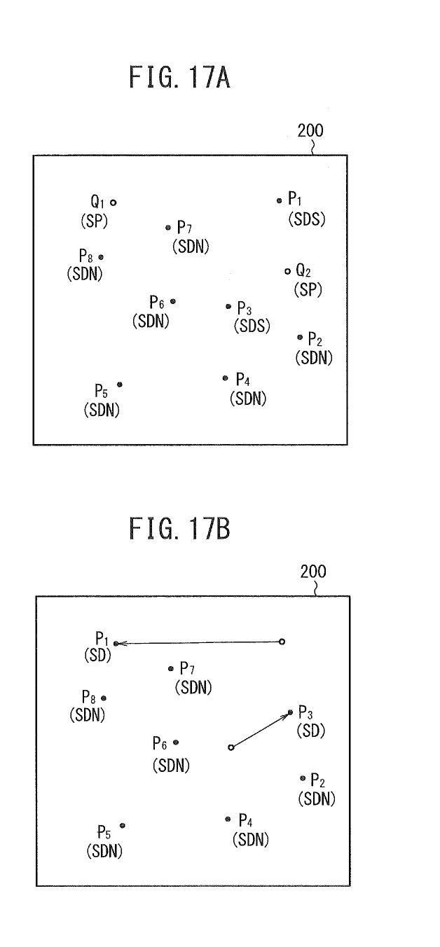

First, the updated candidate position determining unit 30 extracts and determines candidate points SP from the predetermined two-dimensional image region 200 (step S261). The updated candidate position determining unit 30, for example, using a random value supplied from the random number generator 26, determines non-overlapping positions in relation to any of the positions of the seed points SD. The candidate points SP may be a single point or a plurality of points. In the example shown in FIG. 17A, two candidate points SP (point Q₁ and point Q₂) are determined with respect to the eight current seed points SD (points P₁ to P₈).

Next, a portion of the seed points SD and the candidate points SP are exchanged at random (step S262). The updated candidate position determining unit 30 establishes a correspondence randomly between each of the candidate points SP and each of the exchanged (or updated) seed points SD. In FIG. 17A, a correspondence is established between point P₁ and point Q₁, and also between point P₃ and point Q₂. As shown in FIG. 17B, the point P₁ and the point Q₁ are exchanged, and the point P₃ and the point Q₂ are exchanged. In this case, points P₂ and points P₄ to P₈, which are not subject to exchange (or updating), are referred to as first seed points SDN, whereas point P₁ and point P₃, which are subject to exchange (or updating), are referred to as second seed points SDS.

Then, using the exchanged and updated seed points SD (see FIG. 17B), the image data generating unit 40 generates the image data ImgTemp (step S263). At this time, the method used is the same as in the case of step S22 (see FIG. 10), and thus explanations therefor are omitted.

Next, the mesh pattern evaluating unit 42 calculates an evaluation value EVPTemp based on the image data ImgTemp (step S264). At this time, the method used is the same as in the case of step S23 (see FIG. 10), and thus explanations therefor are omitted.

Next, the update probability calculation unit 112 calculates an update probability Prob for updating the positions of the seed points SD (step S265). The phrase “updating the positions” implies determining, as new seed points SD, seed points SD that are tentatively exchanged and obtained in step S262 (i.e., the first seed points SDN and the candidate points SP).

More specifically, in accordance with the Metropolis Criterion, a probability of updating the seed points SD and a probability of not updating the seed points SD are calculated. The update probability Prob is given by the following formula (3).

$$Prob = \{ \begin{matrix}1 & ( if EVPTemp < EVP ) \\ exp ( - \frac{EVPTemp - EVP}{T} ) & ( if EVPTemp ≧ EVP )\end{matrix} \qquad ( 3 )$$

The variable T represents a simulated temperature, wherein, in accordance with the simulated temperature T approaching an absolute temperature (T=0), the updating rule for the seed points SD changes from stochastic to deterministic.

Next, in accordance with the update probability Prob calculated by the update probability calculation unit 112, the position update determining unit 114 determines whether or not to update the positions of the seed points SD (step S266). For example, such a determination may be made stochastically using a random number value supplied from the random number generator 26.

In the case that the seed points SD are to be updated, an “update” instruction is given to the storage unit 24, whereas in the case that the seed points SD are not to be updated, a “do not update” instruction is given to the storage unit 24 (steps S267, S268).

In the foregoing manner, step S26 is brought to an end.

Returning to FIG. 10, in accordance with either of the instructions “update” or “do not update”, it is determined whether or not the seed points SD should be updated (step S27). In the case that the seed points SD are not updated, step S28 is not performed and the routine proceeds directly to step S29.

On the other hand, in the case that the seed points SD are to be updated, in step S28, the storage unit 24 overwrites and updates the presently stored image data Img with the image data ImgTemp determined in step S263 (see FIG. 16). Further, also in step S28, the storage unit 24 overwrites and updates the presently stored evaluation value EVP with the evaluation value EVPTemp determined in step S264 (see FIG. 16). Furthermore, also in step S28, the storage unit 24 overwrites and updates the presently stored position data SDSd of the second seed points SDS with the position data SPd of the candidate points SP determined in step S261 (see FIG. 16). Thereafter, the routine proceeds to step S29.

Next, the counter 108 increments the value of K at the present time by 1 (step S29).

Then, the counter 108 compares a magnitude relationship between the value of K at the present time and the predetermined value of Kmax (step S30). If the value of K is smaller than Kmax, then the process returns to step S26, and steps S26 to S30 thereafter are repeated. In this case, in order to sufficiently ensure convergence at an optimized calculation, the value of Kmax can be set, for example, at Kmax=10000.

In cases apart therefrom, the simulated temperature management unit 110 decrements the simulated temperature T by ΔT (step S31) and then proceeds to step S32. The change in the simulated temperature T is not limited to being decremented by ΔT, but the simulated temperature T may also be multiplied by a fixed constant δ (0<δ<1). In this case, the update probability Prob (lower) indicated in formula (3) is decremented by a constant value.

Next, the simulated temperature management unit 110 determines whether or not, at the present time, the simulated temperature T is equivalent to zero (step S32). If T is not equal to zero, then the process returns to step S25, and steps S25 to S32 are repeated.

On the other hand, if T is equivalent to zero, then the simulated temperature management unit 110 issues a notification to the output image data determining unit 116 to the effect that evaluation of the mesh pattern by the SA method has been completed. In addition, the storage unit 24 overwrites the content of the updated image data Img, which was updated for the last time in step S28, onto the output image data ImgOut, thereby updating the same (step S33).

In this manner, step S2 is brought to an end. Thereafter, the output image data ImgOut is supplied to the exposure data conversion unit 34, and then converted into a control signal for the exposure unit 18. The generated image output data ImgOut is used for outputting and forming the metallic thin wires 54. For example, in the case that the conductive sheet 14 is manufactured by way of exposure, the output image data ImgOut is used as exposure data, or for fabricating a photomask pattern. Further, in the case that the conductive sheet 14 is manufactured by printing including screen printing or inkjet printing, the output image data ImgOut is used as printing data.

In addition, so that the operator can visually confirm the data, the obtained output image data ImgOut may be displayed on the display device 22, and the mesh pattern M may be made visual in a simulated manner. Below, an example shall be described of actual visual results of the output image data ImgOut.

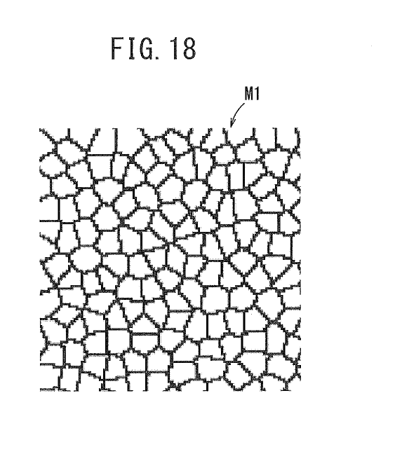

FIG. 18 is an outline explanatory drawing in which, using optimized output image data ImgOut, the mesh pattern M1, which represents the pattern of the conductive sheet 14, is made visual.

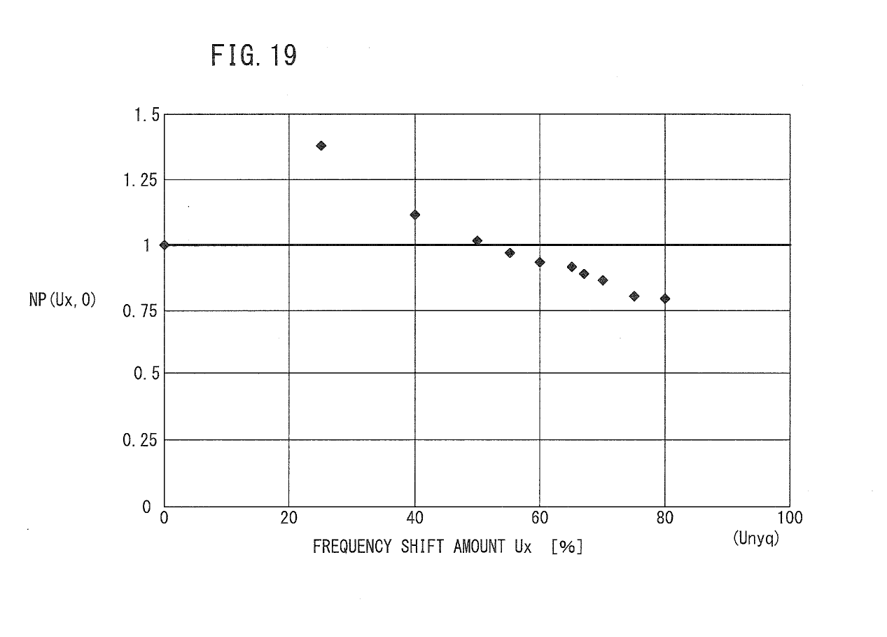

FIG. 19 is a graph showing the result of convoluting the standard human visual response characteristic with respect to the spectrum Spc of the output image data ImgOut shown in FIG. 18. The horizontal axis of the graph is a shift amount (units: %) of spatial frequency, with the Nyquist frequency Unyq serving as a reference (100%). The vertical axis of the graph is the noise intensity NP (Ux, 0) along the Ux-axis direction, with the noise intensity NP(0, 0) at zero spatial frequency serving as a reference.

As shown in the present drawing, the noise intensity NP (Ux, 0) has a peak in the vicinity of Ux=0.25·Unyq, and exhibits a characteristic in which the noise intensity NP (Ux, 0) decreases monotonically as the spatial frequency becomes higher. In the case that the spatial frequency range is 0.25·Unyq≦Ux≦0.5·Unyq, the relationship NP(Ux, Uy)>NP(0, 0) normally is satisfied. Further, in relation to the noise intensity NP(Ux, Uy), without being limited to the Ux-axis, the same relationship is obtained in the radial direction of Spatial Frequency U=(Ux²+Uy²)^{1/2}.

Returning to FIG. 6, the exposure unit 18 carries out an exposure process for the mesh pattern M (step S3), and thereafter, development processing is carried out (step S4).

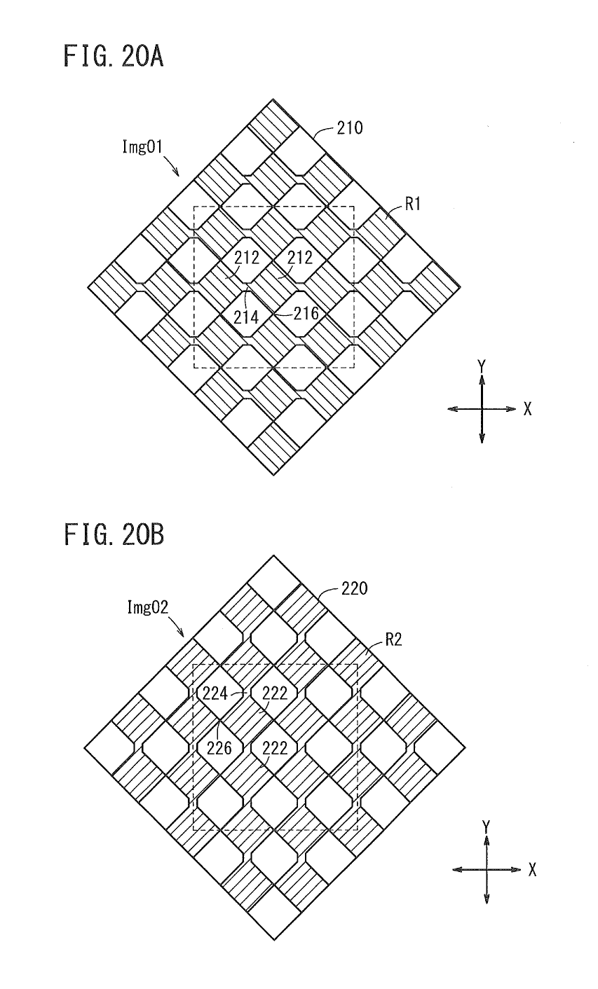

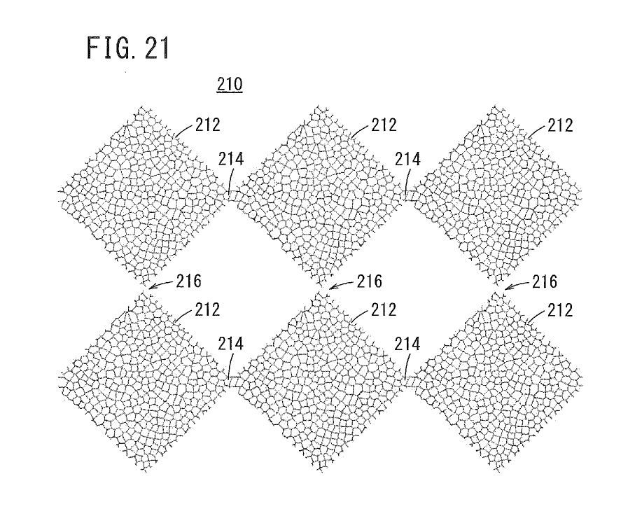

The operator sets an unexposed first sheet (first conductive sheet 14a) in a predetermined position. In addition, responsive to an instruction operation to start exposure, the image cutout unit 32 (see FIG. 1) cuts out two respective image data from the output image data ImgOut acquired from the storage unit 24. First image data ImgO1 for forming the first conductive sheet 14a will be explained with reference to FIGS. 20A and 21.

FIG. 20A is an outline explanatory drawing in which the first image data ImgO1 are made visual. FIG. 21 is a partially enlarged view of a two-dimensional image region 210 shown in FIG. 20A. For facilitating explanation, the first image data ImgO1 are indicated in a state of being rotated clockwise by 45 degrees.

A first image region R1 (the region shown in hatching) having a checkerboard pattern, in which roughly uniformly sized first primitive lattices 212 are arranged alternately and periodically, is formed in the two-dimensional image region 210 represented by the first image data ImgO1. The first primitive lattices 212 are substantially square shaped (diamond shaped), respectively. Between respective first primitive lattices 212, which lie adjacent to each other in the direction of the arrow X, first connecting portions 214 for mutually connecting the first primitive lattices 212 are formed. On the other hand, gaps 216 of a predetermined width are formed between respective first primitive lattices 212 that lie adjacent to each other in the direction of the arrow Y. More specifically, the respective first primitive lattices 212 are connected together mutually only in the direction of the arrow X. Consequently, in relation to the first conductive sheet 14a corresponding to the first image data ImgO1, the respective first primitive lattices 212 that constitute the plural first conductive portions 50a (see FIGS. 2A and 3) are connected together electrically only in the direction of the arrow X. On remaining areas (blank regions) within the two-dimensional image region 210 exclusive of the first image region R1, exposure data that do not form the first conductive portions 50a (see FIGS. 2A and 3) at positions corresponding to the remaining areas, are set.

The length of sides of the first primitive lattices 212 preferably is of a pixel number corresponding to 3 to 10 mm in actual size, and more preferably, is of a pixel number corresponding to 4 to 6 mm in actual size.

Returning to FIG. 1, the image cutout unit 32 supplies the first image data ImgO1 to the exposure data conversion unit 34. The exposure data conversion unit 34 converts the first image data ImgO1 acquired from the image cutout unit 32 into exposure data responsive to the output characteristics of the exposure unit 18. Additionally, the exposure unit 18 carries out an exposure process by applying light 16 toward the first sheet.

Next, the operator sets an unexposed second sheet (second conductive sheet 14b) in place of the first sheet (first conductive sheet 14a) on which exposure is completed. In addition, responsive to an instruction operation to start exposure, the image cutout unit 32 (see FIG. 1) cuts out two respective image data from the output image data ImgOut acquired from the storage unit 24. Second image data ImgO2 for forming the second conductive sheet 14b will be explained with reference to FIG. 20B.

FIG. 20B is an outline explanatory drawing in which the second image data ImgO2 are made visual. For facilitating explanation, the second image data ImgO2 are indicated in a state of being rotated clockwise by 45 degrees.

A second image region R2 (the region shown in hatching) having a checkerboard pattern, in which roughly uniformly sized second primitive lattices 222 are arranged alternately and periodically, is formed in the two-dimensional image region 220 represented by the second image data ImgO2. The second primitive lattices 222 are substantially square shaped (diamond shaped), respectively, and have the same shape as the first primitive lattices 212.

Between respective second primitive lattices 222, which lie adjacent to each other in the direction of the arrow Y, second connecting portions 224 for mutually connecting the second primitive lattices 222 are formed. On the other hand, gaps 226 of a predetermined width are formed between respective second primitive lattices 222 that lie adjacent to each other in the direction of the arrow X. More specifically, the respective second primitive lattices 222 are connected together mutually only in the direction of the arrow Y. Consequently, in relation to the second conductive sheet 14b corresponding to the second image data ImgO2, the respective second primitive lattices 222 that constitute the plural second conductive portions 50b (see FIGS. 2A and 3) are connected together electrically only in the direction of the arrow Y. On remaining areas (blank regions) within the two-dimensional image region 220 exclusive of the second image region R2, exposure data that do not form the second conductive portions 50b (see FIGS. 2A and 3) at positions corresponding to the remaining areas, are set.

As shown in FIGS. 20A and 20B, in the two-dimensional image region 200, the second image region R2 includes at least the remaining areas of the first image region R1. More specifically, in the event that the two-dimensional image regions 210 and 220 are superimposed at the rectangular area shown by the dashed line, the first image region R1 and the second image region R2 have a mutually differing positional relationship, or stated otherwise, a positional relationship in which each of the first primitive lattices 212 and the second primitive lattices 222 do not overlap with each other.

In this manner, by making up the pattern of the mesh pattern M, for example, in applications such as touch panels or the like, even in the case of adopting a structure in which plural conductive sheets (first conductive sheet 14a, second conductive sheet 14b) are stacked, the occurrence of noise interference (moiré patterns) can be prevented.

Although portions of the first connecting portions 214 (see FIG. 20A) and the second connecting portions 224 (see FIG. 20B) are partially overlapped, by minimizing the area (area ratio with respect to the two-dimensional image regions 210, 220) thereof to be extremely small, adverse visual effects can be eliminated.

Returning to FIG. 1, the exposure data conversion unit 34 converts the second image data ImgO2 acquired from the image cutout unit 32 into exposure data responsive to the output characteristics of the exposure unit 18. In addition, an exposure process is carried out by applying light 16 toward the second sheet.

Next, a description will be made of a detailed method of manufacturing the first conductive sheet 14a and the second conductive sheet 14b.

For example, by exposing to light a photosensitive material including an emulsion layer containing a photosensitive silver halide salt on the first transparent substrate 56a and the second transparent substrate 56b, and carrying out development processing thereon, metallic silver portions and light permeable portions may be formed respectively in the exposed and non-exposed areas, to thereby form the first conductive portions 50a and the second conductive portions 50b. Moreover, by further implementing at least one of a physical development treatment and a plating treatment on the metallic silver portions, a conductive metal may be deposited on the metallic silver portions.

Alternatively, the first conductive portions 50a and the second conductive portions 50b may be formed by exposing to light a photoresist film on a copper foil, which is formed on the first transparent substrate 56a and the second transparent substrate 56b, carrying out development processing to form a resist pattern, and then etching the exposed copper foil from the resist pattern.

Alternatively, the first conductive portions 50a and the second conductive portions 50b may be formed by printing a paste, which includes metallic particles therein, on the first transparent substrate 56a and the second transparent substrate 56b, and carrying out metallic plating on the paste.

The first conductive portions 50a and the second conductive portions 50b may also be formed by printing using a screen printing plate or a gravure printing plate on the first transparent substrate 56a and the second transparent substrate 56b.

The first conductive portions 50a and the second conductive portions 50b may also be formed by inkjet printing, which is carried out on the first transparent substrate 56a and the second transparent substrate 56b.

Next, a technique will be discussed focusing on use of a photographic photosensitive silver halide material, which is a particularly preferred embodiment, on the first conductive sheet 14a and the second conductive sheet 14b according to the present embodiment.

The method of manufacturing the first conductive sheet 14a and the second conductive sheet 14b according to the present embodiment includes the following three processes, depending on the photosensitive materials and development treatments.

(1) A process comprising subjecting a photosensitive black-and-white silver halide material free of physical development nuclei to a chemical or thermal development, to form the metallic silver portions on the photosensitive material.

(2) A process comprising subjecting a photosensitive black-and-white silver halide material having a silver halide emulsion layer containing physical development nuclei to a solution physical development process, to thereby form the metallic silver portions on the photosensitive material.

(3) A process comprising subjecting a stack of a photosensitive black-and-white silver halide material free of physical development nuclei and an image-receiving sheet having a non-photosensitive layer containing physical development nuclei to a diffusion transfer development, to form the metallic silver portions on the non-photosensitive image-receiving sheet.

In process (1), an integral black-and-white development procedure is used to form a transmittable conductive film such as a light-transmitting conductive film on the photosensitive material. The resulting silver is chemically or thermally developed silver containing a high-specific surface area filament, and thereby shows a high activity in the following plating or physical development treatment.

In process (2), silver halide particles are melted around the physical development nuclei and deposited on the nuclei in the exposed areas, to form a transmittable conductive film, such as a light-transmitting conductive film, on the photosensitive material. Also in this process, an integral black-and-white development procedure is used. Although high activity can be achieved since the silver halide is deposited on the physical development nuclei during development, the developed silver has a spherical shape with a small specific surface.

In process (3), silver halide particles are melted in unexposed areas, and diffused and deposited on the development nuclei of the image-receiving sheet, to form a transmittable conductive film, such as a light-transmitting conductive film, on the sheet. In this process, a so-called separation-type procedure is used, and the image-receiving sheet is peeled off from the photosensitive material.

A negative or reversal development treatment can be used in any of the foregoing processes. In the diffusion transfer development, the negative development treatment can be carried out using an auto-positive photosensitive material.

The chemical development, thermal development, solution physical development, and diffusion transfer development have the meanings generally known in the art, and are explained in common photographic chemistry texts such as Shinichi Kikuchi, “Shashin Kagaku (Photographic Chemistry)”, Kyoritsu Shuppan Co., Ltd., 1955, and C. E. K. Mees, “The Theory of Photographic Processes, 4th ed.”, McMillan, 1977. A liquid treatment is generally used in the present invention, and also a thermal development treatment can be utilized. For example, the techniques described in Japanese Laid-Open Patent Publication Nos. 2004-184693, 2004-334077, and 2005-010752, and Japanese Patent Application Nos. 2004-244080 and 2004-085655 can be used in the present invention.

An explanation shall now be given in relation to the structures of each of the first conductive sheet 14a and the second conductive sheet 14b according to the present embodiment.

### [First Transparent Substrate 56a, Second Transparent Substrate 56b]

Plastic films, plastic plates, glass plates or the like can be given as examples of materials to be used as the first transparent substrate 56a and the second transparent substrate 56b.

As materials for the aforementioned plastic film and plastic plate, there can be used, for example, polyesters such as polyethylene terephthalate (PET), polyethylene naphthalate (PEN), etc., polyolefins such as polyethylene (PE), polypropylene (PP), polystyrene, EVA, etc., vinyl resins, and apart therefrom, polycarbonate (PC), polyamide, polyimide, acrylic resin, triacetyl cellulose (TAC), etc.

As materials for the first transparent substrate 56a and the second transparent substrate 56b, preferably, plastic films or plastic plates having a melting point less than or equal to about 290° C. are used, for example, PET (melting point: 258° C.), PEN (melting point: 269° C.), PE (melting point: 135° C.), PP (melting point: 163° C.), polystyrene (melting point: 230° C.), polyvinyl chloride (melting point: 180° C.), polyvinylidene chloride (melting point: 212° C.), and TAC (melting point: 290° C.), etc. From the standpoints of optical transparency and workability, etc., PET is particularly preferred. Since transparency is demanded for conductive sheets such as the first conductive sheet 14a and the second conductive sheet 14b, preferably, a high degree of transparency is provided for the first transparent substrate 56a and the second transparent substrate 56b.

### [Silver Halide Emulsion Layer]

The silver halide emulsion layer that forms the first conductive sheet 14a and the second conductive sheet 14b (i.e., conductive portions such as the first primitive lattices 212, the first connecting portions 214, the second primitive lattices 222, the second connecting portions 224, etc. See FIGS. 20A and 20B), may include additives such as solvents and dyes in addition to silver salt and a binder.

The silver salt used in the present embodiment may include an inorganic silver salt such as a silver halide and an organic silver salt such as silver acetate or the like. Preferably, silver halide is used, which has excellent light sensing properties.

The coated silver amount (silver salt coating amount) of the silver halide emulsion layer, in terms of the silver therein, preferably is 1 to 30 g/m², more preferably is 1 to 25 g/m², and still more preferably is 5 to 20 g/m². By keeping the silver coating amount within the above-described ranges, desirable surface resistance can be obtained in the case that the first conductive sheet 14a and the second conductive sheet 14b are stacked.

As examples of binders that are used in the present embodiment, there may be used, for example, gelatins, polyvinyl alcohols (PVA), polyvinyl pyrolidones (PVP), polysaccharides such as starches, celluloses and derivatives thereof, polyethylene oxides, polyvinylamines, chitosans, polylysines, polyacrylic acids, polyalginic acids, polyhyaluronic acids, and carboxycelluloses. The binders exhibit neutral, anionic, or cationic properties depending on the ionic properties of the functional group.

The contained weight of the binder that is included in the silver salt emulsion layer of the present embodiment is not particularly limited, but can be determined suitably from within a range that exhibits properties of good dispersibility and adhesion. The contained weight of the binder in the silver salt emulsion layer preferably is 1/4 or greater, and more preferably, is 1/2 or greater in terms of the silver/binder volume ratio. The silver to binder (silver/binder) volume ratio is preferably 100/1 or less, and more preferably, is 50/1 or less. Further, the silver to binder volume ratio is preferably 1/1 to 4/1, and most preferably is 1/1 to 3/1. By maintaining the silver to binder volume ratio of the silver salt emulsion layer within such ranges, even in the event that the amount of the silver coating is adjusted, variance in resistance is suppressed, and a conductive sheet 14 having uniform surface resistance can be obtained. Incidentally, the silver to binder volume ratio can be determined by converting the silver halide amount/binder amount of the raw materials (weight ratio) into a silver amount/binder amount (weight ratio), and furthermore, by converting the silver amount/binder amount (weight ratio) into a silver amount/binder amount (volume ratio).

### <Solvents>

Solvents used in forming the silver salt emulsion layer are not particularly limited. The following solvents can be cited as examples: water, organic solvents (e.g., alcohols such as methanol, ketones such as acetone, amides such as formamide, sulfoxides such as dimethyl sulfoxide, esters such as ethyl acetate, and ethers), ionic liquids, and mixtures of such solvents.

The contained amount of the solvent that is used in the silver salt emulsion layer of the present embodiment lies within a range of 30 to 90 percent-by-mass with respect to the total mass of the silver salt, the binder, etc., contained within the silver salt emulsion layer, and preferably, lies within a range of 50 to 80 percent-by-mass.

### <Other Additive Agents>

In relation to various additives used in the present embodiment, the additives are not limited, and preferably, known types of such additives can be used.

### [Other Layer Structures]

A non-illustrated protective layer may be disposed on the silver salt emulsion layer. In the present embodiment, the term “protective layer” means a layer made from a binder such as a gelatin or a high-molecular polymer, which is formed on the silver salt emulsion layer having photosensitivity for realizing an effect of improved mechanical characteristics and resistance to scratching. The thickness thereof preferably is 0.5 μm or less. The coating method and formation method of the protective layer are not limited to any particular methods, but can be appropriately selected from among known coating and forming methods. Further, an undercoat layer, for example, can be disposed underneath the silver salt emulsion layer.

Next, respective steps of a method of manufacturing the first conductive sheet 14a and the second conductive sheet 14b will be described.

### [Exposure]

In the present embodiment, although a case has been described in which the first conductive portions 50a and the second conductive portions 50b are implemented by means of a printing technique, apart from using a printing technique, the first conductive portions 50a and the second conductive portions 50b may be formed by exposure, development, etc. More specifically, exposure is carried out on the photosensitive material including the silver salt-containing layer, or on the photosensitive material on which the photolithographic photopolymer is coated, which is disposed on the first transparent substrate 56a and the second transparent substrate 56b. Exposure can be carried out by use of electromagnetic waves. For example, light such as visible light or ultraviolet light, or radiation such as X-rays or the like may be used to generate electromagnetic waves. Exposure may also be carried out using a light source having a wavelength distribution or a specific wavelength.

### [Development Treatment]

In the present embodiment, after exposure of the emulsion layer, the emulsion layer is further subjected to a development treatment. The development treatment can be performed using common development treatment technologies for silver halide photographic films, photographic papers, printing plate films, emulsion masks for photomasking, and the like. Although not particularly limited, the developer for the development treatment may be a PQ developer, an MQ developer, an MAA developer, etc. Examples of commercially available developers usable in the present invention include CN-16, CR-56, CP45X, FD-3, and PAPITOL, available from FUJIFILM Corporation, and C-41, E-6, RA-4, D-19, and D-72, available from Eastman Kodak Company, as well as other developers contained in kits. Further, the developer may be a lith developer.

The development process according to the present invention can include a fixing process, which is carried out with the aim of stabilizing by removing unexposed portions of the silver salt. The fixing process in the present invention can utilize a fixing technique that makes use of a silver halide photographic film, photographic paper, a printing plate film, an emulsion mask for a photomask or the like.

The fixing temperature in the aforementioned fixing step preferably is about 20° C. to about 50° C., and more preferably, is 25° C. to 45° C. Further, the fixing time preferably is 5 seconds to 1 minute, and more preferably, is 7 seconds to 50 seconds. The amount of replenishment of the fixing solution is preferably 600 ml/m² or less, more preferably is 500 ml/m² or less, and particularly preferably, is 300 ml/m² or less with respect to the processing amount of the photosensitive material.

Preferably, at least one of a water washing process and a stabilization treatment is carried out on the photosensitive material on which the development and fixing processes have been implemented. In the water washing process and the stabilization treatment, the amount of washing water that is used can typically be 20 liters or less per 1 m² of the photosensitive material, and the amount of replenishment may be 3 liters or less (including zero, i.e., using a fixed amount of reserved water).

The amount by mass of the metallic silver included in the exposed portions after the development process preferably is of a content ratio of 50 percent by mass or greater, and more preferably is 80 percent by mass or greater, with respect to the amount by mass of the silver contained in the exposed portion prior to being exposed. If the amount by mass of the silver contained in the exposed portion is 50 percent by mass or greater with respect to the amount by mass of the silver contained in the exposed portion prior to being exposed, then a high degree of conductivity can be obtained.

In the present embodiment, the gradation obtained following development is preferably in excess of 4.0, although no particularly limit is placed thereon. In the case that the gradation exceeds 4.0 after development, the conductivity of the conductive metal portion can be increased while maintaining high transmittance of the light-transmitting portion. For example, a gradation of 4.0 or greater can be obtained by doping with rhodium or iridium ions.

The conductive sheet is obtained by the above steps. The surface resistance of the resultant conductive sheet is preferably within a range of 0.1 to 100 ohm/sq, and more preferably, is within a range of 1 to 10 ohm/sq. The conductive sheet may further be subjected to a calendaring treatment after the development treatment. By means of a calendaring treatment, adjustment to a desired surface resistance can be achieved.

### [Physical Development and Plating Treatments]

In the present embodiment, in order to improve the conductivity of the metallic silver portion formed by the above exposure and development treatments, conductive metal particles may be deposited on the metallic silver portion by at least one of a physical development treatment and a plating treatment. In the present invention, the conductive metal particles may be deposited on the metallic silver portion by only one of the physical development and plating treatments, or by a combination of such treatments. The metallic silver portion, which is subjected to at least one of a physical development treatment and a plating treatment in this manner, may also be referred to as a “conductive metal portion”, as well as the metallic silver portion itself.

In the present embodiment, “physical development” refers to a process in which metal ions such as silver ions are reduced by a reducing agent, whereby metal particles are deposited on a metal or metal compound core. Such physical development has been used in the fields of instant B&W film, instant slide film, printing plate production, etc., and similar technologies can be used in the present invention. Physical development may be carried out at the same time as the above development treatment following exposure, or may be carried out separately after completion of the development treatment.

In the present embodiment, the plating treatment may contain non-electrolytic plating (such as chemical reduction plating or displacement plating), electrolytic plating, or a combination of both non-electrolytic plating and electrolytic plating. Known non-electrolytic plating technologies, for example, technologies used in printed circuit boards, etc., may be used in the present embodiment. Preferably, electroless copper plating is used in the case of such non-electrolytic plating.

### [Oxidation Treatment]

In the present embodiment, the metallic silver portion following the development treatment and the conductive metal portion, which is formed by at least one of the physical development treatment and the plating treatment, preferably are subjected to an oxidation treatment. For example, by the oxidation treatment, a small amount of metal deposited on the light-transmitting portion can be removed, so that the transmittance of the light-transmitting portion can be increased to roughly 100%.

### [Conductive Metal Portion]

In the present embodiment, the lower limit of the line width of the conductive metal portion (i.e., the line width of the metal wires of the first conductive portions 50a and the second conductive portions 50b) preferably is 1 μm or greater, 3 μm or greater, 4 μm or greater, or 5 μm or greater, whereas the upper limit thereof preferably is 15 μm, 10 μm or less, 9 μm or less, or 8 μm or less. If the line width is less than the aforementioned lower limit, since conductivity becomes insufficient, in the case of being used for a touch panel, the detection sensitivity thereof also becomes insufficient. On the other hand, if the line width exceeds the aforementioned upper limit, moiré patterns tend to become noticeable due to the conductive metal portions, and thus visibility may be worsened in the case of being used as a touch panel. By setting the line width within the above range, the occurrence of moiré patterns is prevented, and in particular the visibility is improved. Further, the conductive metal portion may have a part with a line width in excess of 200 μm for the purpose of providing a ground connection, etc.

In the present embodiment, from the standpoint of visible light transmittance, the opening ratio (transmittance) of the conductive metal portion is preferably 85% or greater, more preferably, is 90% or greater, and most preferably, is 95% or greater. The opening ratio is the ratio of the light-transmitting portions to the whole, where the light-transmitting portions are the whole without the conductive portions such as the first primitive lattices 212, the first connecting portions 214, the second primitive lattices 222, the second connecting portions 224, etc. (see FIGS. 20A and 20B). For example, a square lattice having a line width of 15 μm and a pitch of 300 μm has an opening ratio of 90%.

### [Light Transmitting Portions]

The term “light transmitting portions” in the present embodiment implies the portions (openings 52) that are light-transmissive, apart from the conductive metallic portions in the first conductive sheet 14a and the second conductive sheet 14b. As described above, the transmittance of the light-transmitting portions, which is a minimum transmittance value in a wavelength region of 380 to 780 nm obtained neglecting the light absorption and reflection of the first transparent substrate 56a and the second transparent substrate 56b, is 90% or greater, preferably 95% or greater, more preferably 97% or greater, further preferably 98% or greater, and most preferably 99% or greater.

Concerning the exposure method, a method performed via a glass mask, or a lithography exposure by way of laser is preferred.

### [First Conductive Sheet 14a and Second Conductive Sheet 14b]

In the first conductive sheet 14a and the second conductive sheet 14b according to the present embodiment, the thickness of the first transparent substrate 56a and the second transparent substrate 56b preferably is 5 to 350 μm, and more preferably, is 30 to 150 μm. In the case that the thickness thereof is 5 to 350 μm, a desired visible light transmittance can be obtained, and the substrates can be handled easily.

The thickness of the metallic silver portion formed on the first transparent substrate 56a and the second transparent substrate 56b can be appropriately selected by controlling the thickness of the coating material for the silver salt-containing layer applied to the first and second transparent substrates 56a, 56b. The thickness of the metallic silver portion may be selected within a range of 0.001 mm to 0.2 mm, preferably is 30 μm or less, more preferably, is 20 μm or less, further preferably, is selected within a range of 0.01 to 9 μm, and most preferably, is selected within a range of 0.05 to 5 μm. The metallic silver portion preferably is formed in a patterned shape. The metallic silver portion may have a monolayer structure or a multilayer structure containing two or more layers. In the case that the metallic silver portion has a patterned multilayer structure containing two or more layers, the layers may have different wavelength color sensitivities in order to be sensitive to different wavelength. In this case, different patterns can be formed in the layers by use of exposure lights having different wavelengths.

For use in a touch panel, the conductive metal portion preferably has a small thickness because the viewing angle and visibility of the display panel are improved owing to such a small thickness. Thus, the thickness of the layer of the conductive metal on the conductive metal portion preferably is less than 9 μm, more preferably, is 0.1 μm or more but less than 5 μm, and further preferably, is 0.1 μm or more but less than 3 μm.

In the present embodiment, as noted above, the thickness of the metallic silver portion can be controlled by changing the coating thickness of the silver salt-containing layer, and the thickness of the conductive metal particle layer can be controlled in at least one of the physical development treatment and the plating treatment, whereby the first conductive sheet 14a and the second conductive sheet 14b having a thickness of less than 5 μm, and more preferably, less than 3 μm, can easily be produced.

Plating or the like need not necessarily be carried out in the method of manufacturing the first conductive sheet 14a and the second conductive sheet 14b according to the present embodiment. This is because, in the method of manufacturing the first conductive sheet 14a and the second conductive sheet 14b, a desired surface resistance can be obtained by controlling the applied silver amount and the silver/binder volume ratio of the silver salt emulsion layer. A calendaring treatment or the like may also be carried out as necessary.

### (Hardening Treatment Following Development Treatment)

It is preferred, after the silver salt emulsion layer has been developed, for the resultant product to be immersed in a hardener and subjected to a hardening treatment. Examples of suitable hardeners, for example, can include dialdehyde type hardeners such as glutaraldehyde, adipaldehyde, and 2,3-dihydroxy-1,4-dioxane, and boric acid type hardeners, as described in Japanese Laid-Open Patent Publication No. 02-141279.

### [Stacked Conductive Sheet]

The stacked conductive sheet may be applied to a functional layer such as a hard coat layer or an antireflective layer.

In the present invention, the technologies of the following Japanese Laid-Open Patent Publications and PCT International Publication Numbers shown in Tables 1 and 2 can appropriately be used in combination. In the following Tables 1 and 2, conventional notations such as “Japanese Laid-Open Patent Publication No.”, “Publication No.”, “Pamphlet No. WO”, etc., have been omitted.

TABLE 1

| | | | | |
|---|---|---|---|---|
| 2004-221564 | 2004-221565 | 2007-200922 | 2006-352073 | 2007-129205 |
| 2007-235115 | 2007-207987 | 2006-012935 | 2006-010795 | 2006-228469 |
| 2006-332459 | 2009-21153 | 2007-226215 | 2006-261315 | 2007-072171 |
| 2007-102200 | 2006-228473 | 2006-269795 | 2006-269795 | 2006-324203 |
| 2006-228478 | 2006-228836 | 2007-009326 | 2006-336090 | 2006-336099 |
| 2006-348351 | 2007-270321 | 2007-270322 | 2007-201378 | 2007-335729 |
| 2007-134439 | 2007-149760 | 2007-208133 | 2007-178915 | 2007-334325 |
| 2007-310091 | 2007-116137 | 2007-088219 | 2007-207883 | 2007-013130 |
| 2005-302508 | 2008-218784 | 2008-227350 | 2008-227351 | 2008-244067 |
| 2008-267814 | 2008-270405 | 2008-277675 | 2008-277676 | 2008-282840 |
| 2008-283029 | 2008-288305 | 2008-288419 | 2008-300720 | 2008-300721 |
| 2009-4213 | 2009-10001 | 2009-16526 | 2009-21334 | 2009-26933 |
| 2008-147507 | 2008-159770 | 2008-159771 | 2008-171568 | 2008-198388 |
| 2008-218096 | 2008-218264 | 2008-224916 | 2008-235224 | 2008-235467 |
| 2008-241987 | 2008-251274 | 2008-251275 | 2008-252046 | 2008-277428 |

TABLE 2

| | | | | |
|---|---|---|---|---|
| 2006/001461 | 2006/088059 | 2006/098333 | 2006/098336 | 2006/098338 |
| 2006/098335 | 2006/098334 | 2007/001008 | | |

### EXAMPLES

Examples of the present invention will be described more specifically below. Materials, amounts, ratios, treatment contents, treatment procedures, and the like, used in the examples may be appropriately changed without departing from the essential scope of the present invention. Therefore, the following specific examples should be considered in all respects as illustrative and not restrictive.

### (Photosensitive Silver Halide Material)

An emulsion containing an aqueous medium, gelatin and silver iodobromochloride particles was prepared. The amount of gelatin was 10.0 g per 150 g of Ag in the aqueous medium. The silver iodobromochloride particles therein had an I content of 0.2 mol %, a Br content of 40 mol %, and an average spherical equivalent diameter of 0.1 μm.

K₃Rh₂Br₉ and K₂IrCl₆ were added to the emulsion at a concentration of 10⁻⁷ mol/mol-Ag in order to dope the silver bromide particles with Rh and Ir ions. Na₂PdCl₄ was further added to the emulsion, and the resultant emulsion was subjected to gold-sulfur sensitization using chlorauric acid and sodium thiosulfate. Thereafter, the emulsion and a gelatin hardening agent were applied to each of a first transparent substrate 56a and a second transparent substrate 56b, both composed of polyethylene terephthalate (PET), such that the amount of applied silver was 10 g/m². The Ag/gelatin volume ratio was 2/1.

The PET support body had a width of 30 cm, and the emulsion was applied thereto at a width of 25 cm and a length of 20 m. Both end portions having a width of 3 cm were cut off from the PET support body in order to obtain a roll-shaped photosensitive silver halide material having a central coating width of 24 cm.

### (Generation of Exposure Pattern)

Using the SA method as described for the present embodiment (see FIG. 11), output image data ImgOut representing the mesh pattern M (see FIG. 2A), which was made up from irregularly arranged wirings, were created.

The set conditions for the mesh pattern M were established such that the total transmittance was 93%, the thickness of the substrate (sum of the first and second transparent substrates 56a, 56b) was 40 μm, the width of the metallic thin wires 54 was 20 μm, and the thickness of the metallic thin wires 54 was 10 μm. The pattern size was set to 5 mm both vertically and horizontally, and the image resolution was set to 3500 dpi (dots per inch). Initial positions of the seed points SD were determined randomly using a Mersenne Twister algorithm, and respective polygonal mesh areas were defined using a Voronoi diagram. Evaluation values EVP were calculated based on the L*, a*, b* image data color values of the image data Img. In addition, the same output image data ImgOut were arranged alongside one another in both vertical and horizontal directions to create periodic exposure patterns. As a result, the output image data ImgOut that represents the pattern of the mesh pattern M1 (see FIG. 18) was obtained.

In addition, as shown in FIGS. 20A and 20B, a cutting process was carried out on the output image data ImgOut. The length of one side of the first primitive lattices 212 and the second primitive lattices 222 was set at 5.4 mm, and the width of the first connecting portions 214 and the second connecting portions 224 was set at 0.4 mm. Both of the gaps 216, 226 were 0.4 mm.

### (Exposure)

Exposure was carried out on the first transparent substrate 56a and the second transparent substrate 56b of an A4 (210 mm×297 mm) sized area, by using the pattern shown in FIG. 20A for the first conductive sheet 14a, and the pattern shown in FIG. 20B for the second conductive sheet 14b. Exposure was carried out using parallel light from a high-pressure mercury lamp light source, and using the photomasks having the patterns mentioned above.

### (Developing Technique)

The following chemical compounds were included in 1 liter of the developing solution.

| | |
|---|---|
| Hydroquinone | 20 g |
| Sodium sulfite | 50 g |
| Potassium carbonate | 40 g |
| Ethylenediaminetetraacetic acid | 2 g |
| Potassium bromide | 3 g |
| Polyethylene glycol 2000 | 1 g |
| Potassium hydroxide | 4 g |
| pH | controlled at 10.3 |

The following chemical compounds were included in 1 liter of the fixing solution.

| | | |
|---|---|---|
| Ammonium thiosulfate solution (75%) | 300 | ml |
| Ammonium sulfite monohydrate | 25 | g |
| 1,3-Diaminopropanetetraacetic acid | 8 | g |
| Acetic acid | 5 | g |
| Aqueous ammonia (27%) | 1 | g |

| | |
|---|---|
| pH | controlled at 6.2 |

Using the treatment agents as listed above, a development treatment was conducted on the photosensitive material following exposure thereof using an automatic development machine FG-710PTS (manufactured by FUJIFILM Corporation) under the following development conditions; development: 30 seconds at 35° C., fixation: 23 seconds at 34° C., water washing: 20 seconds under running water (5 L/min).

Below, the conductive sheet 14 having the mesh pattern M1 is denoted as a first sample. Metallic thin wires 54 were selected randomly at twenty sites from within the first sample, and the line widths thereof were measured respectively. As a result, the average value of the line widths (average line width) of the metallic thin wires 54 was measured at 19.7 μM. More specifically, the spatial frequency corresponding to the average line width was 25.4 Cy/mm {=1/(2×19.7×10⁻³)}.

### [Evaluation]

### (Measurement of Surface Resistivity)

To evaluate uniformity in surface resistivity, surface resistivities of the conductive sheet 14 were measured at ten arbitrary sites using LORESTA GP (Model MCP-T610) inline 4-pin probe type (ASP), manufactured by Dia Instruments Co., Ltd., to obtain an average value of the surface resistivities.

### (Evaluation of Noise Sensation)

A commercially available color liquid crystal display (screen size: 4.7 type, 640×480 dots) was used. A touch panel on which the first sample was adhered was incorporated into the liquid crystal display, an LED lamp as auxiliary light was lit up from a back surface of a liquid crystal panel, the display screen was observed, and a visual evaluation of noise sensation was carried out. Visual confirmation of such noise was carried out from the front side of the liquid crystal panel at an observation distance of 300 mm.

### [Results]

The sensation of noise exhibited by ten sheets of the first sample was hardly noticeable, and the ten sheets of the first sample having levels sufficiently practical as transparent electrodes and in terms of surface resistivity, and with good transparency, were realized. Based on actual measured values, a graph was created of the convolution integrals, whereby it was confirmed that the same effects shown in FIG. 19 were obtained.

In the foregoing manner, the output image data ImgOut has a characteristic such that, in a convolution integral between the spectrum Spc of the output image data ImgOut and a standard human visual response characteristic (VTF), respective integral values NP(Ux, Uy), which exist in a spatial frequency band equal to or greater than 1/4 of and equal to or less than 1/2 of the Nyquist frequency Unyq corresponding to the output image data ImgOut, are greater than the integral value NP(0, 0). Therefore, compared to the low spatial frequency band side, the noise amount on the side of the high spatial frequency band is relatively large. Although human visual perception has a high response characteristic in a low spatial frequency band, in mid to high spatial frequency bands, properties of the response characteristic decrease rapidly, and thus, the sensation of noise as perceived visually by humans tends to decrease. In accordance with this phenomenon, the sensation of granular noise caused by the pattern of the conductive sheet 14 is lowered, and visibility of objects to be observed can be significantly enhanced. Further, the cross sectional shape of the respective wires after cutting is substantially constant, and thus the conductive sheet exhibits a stable conducting capability.

Further, the same effects can also be obtained with a structure having a characteristic such that, in a convolution integral between the VTF and the spectrum Spc of the conductive sheet 14 as viewed in plan, respective integral values NP(Ux, Uy), which exist in a spatial frequency band equal to or greater than 1/4 the frequency and equal to or less than 1/2 the frequency of the spatial frequency corresponding to the average line width of the conductive portions 50, are greater than the integral value NP(0, 0).

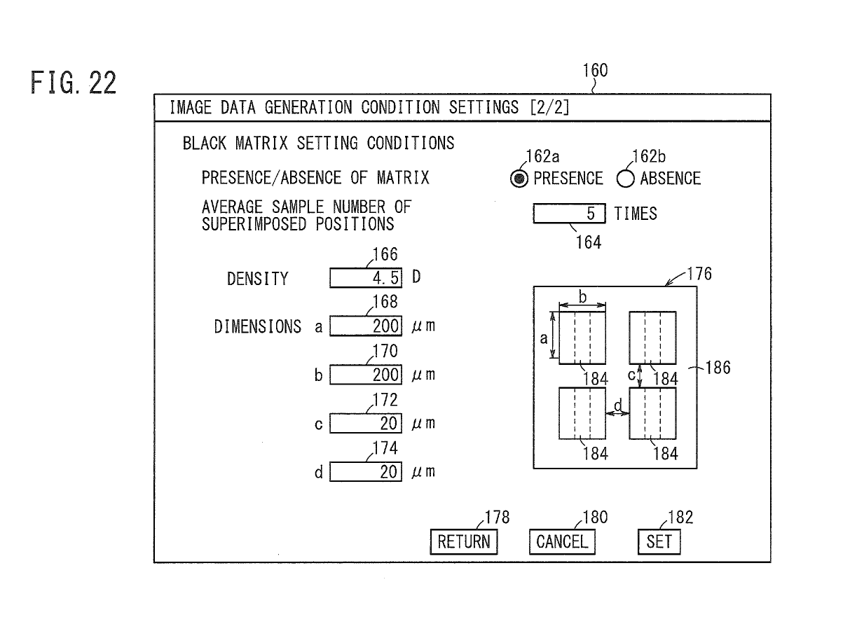

Next, with reference to FIGS. 22 through 25, a modified example of the aforementioned present embodiment will be described. Since the configuration shown in FIGS. 1 through 5 is the same as that of the present embodiment, explanations thereof are omitted. The present modified example differs from the present embodiment in that the mesh pattern M is optimized taking into consideration the pattern of the black matrix 64.

FIG. 22 is a view showing a setting screen for setting image data creating conditions for superimposed image data Img′ according to the modified example of the present embodiment. The superimposed image data Img′ include ImagInit′ (initial data) and ImgTemp′ (intermediate data), to be described later.

The setting screen 160 has, from the top thereof and in the following order, two radio buttons 162a, 162b, six text boxes 164, 166, 168, 170, 172, 174, a matrix-shaped image 176, and buttons 178, 180, 182 labeled “RETURN”, “CANCEL”, and “SET” respectively.

The words “PRESENCE” and “ABSENCE” are displayed respectively to the right of the radio buttons 162a and 162b. In addition, to the left of the radio button 162a, the text label “PRESENCE/ABSENCE OF MATRIX” is displayed.

To the left of the text boxes 164, 166, 168, 170, 172, 174, the text labels, “AVERAGE SAMPLE NUMBER OF SUPERIMPOSED POSITIONS”, “DENSITY”, “DIMENSIONS a”, “b”, “c”, and “d” are displayed respectively. Further, to the right of the text boxes 164, 166, 168, 170, 172, 174, the text labels “TIMES”, “D”, “μm”, “μm”, “μm”, and “μm” are displayed respectively. By performing a predetermined operation using the input device 20 (e.g., a keyboard), Arabic numerals can be entered in any of the text boxes 164, 166, 168, 170, 172, 174.

The matrix-shaped image 176 is an image that simulates the form of the black matrix 64 (see FIG. 2B), and is provided with four openings 184 and a window frame 186.

Next, operations of the manufacturing apparatus 10 according to the present modified example will be described below with reference to the flowcharts of FIGS. 6, 23 and 24.

In the flowchart of FIG. 6, operations of the present modified example are basically the same as those of the present embodiment. However, in the case where the various conditions are input (step S1), not only visual information pertaining to visibility of the mesh pattern M, but in addition, visual information in relation to the black matrix 64 also are input.

The operator inputs appropriate numerical values via the setting screen 160 (see FIG. 22) displayed on the display device 22. As a result, visual information in relation to visibility of the black matrix 64 can be input. Visual information of the black matrix 64 is defined by various types of information that contribute to the shape and optical density of the black matrix 64, and includes visual information of the pattern material. As visual information of the pattern material, for example, there may be included at least one of a type, a color, an optical transmittance, or an optical reflectance of the pattern material, or an arrangement position, a unit shape, or a unit size of the structural pattern may be included in the visual information of the pattern material.

In relation to the black matrix 64 that is to be superimposed, the operator inputs various conditions of the black matrix 64 using the text box 164.

The inputs made via the radio buttons 162a, 162b correspond to whether or not output image data ImgOut is created representing a pattern in which the black matrix 64 is superimposed on the mesh pattern M. If “PRESENCE” (the radio button 162a) is selected, the black matrix is superimposed. If “ABSENCE” (the radio button 162b) is selected, the black matrix 64 is not superimposed.

The value input to the text box 164 randomly determines the arrangement position of the black matrix 64, and corresponds to the number of trials carried out to generate and evaluate the image data Img. For example, in the event the value is set to 5 times, five instances of superimposed image data Img′ are created in which positional relationships are determined randomly between the mesh pattern M and the black matrix 64, and using respective average values of the evaluation value EVP, evaluation of the pattern of the mesh is carried out.

The values of the text boxes 166, 168, 170, 172 correspond to the optical density of the black matrix 64 (units: D), the vertical size of the unit pixel 66 (units: μm), the horizontal size of the unit pixel 66 (units: μm), the width of the light-shielding material 68h (units: μm), and the width of the light-shielding material 68v (units: μm).

Furthermore, based on the optical density of the black matrix 64 (text box 166), the vertical size of the unit pixel 66 (text box 168), the horizontal size of the unit pixel 66 (text box 170), the width of the light-shielding material 68h (text box 172), and the width of the light-shielding material 68v (text box 174), the pattern of the mesh pattern M (i.e., the shape and optical density) in the case that the black matrix 64 is superimposed can be estimated.

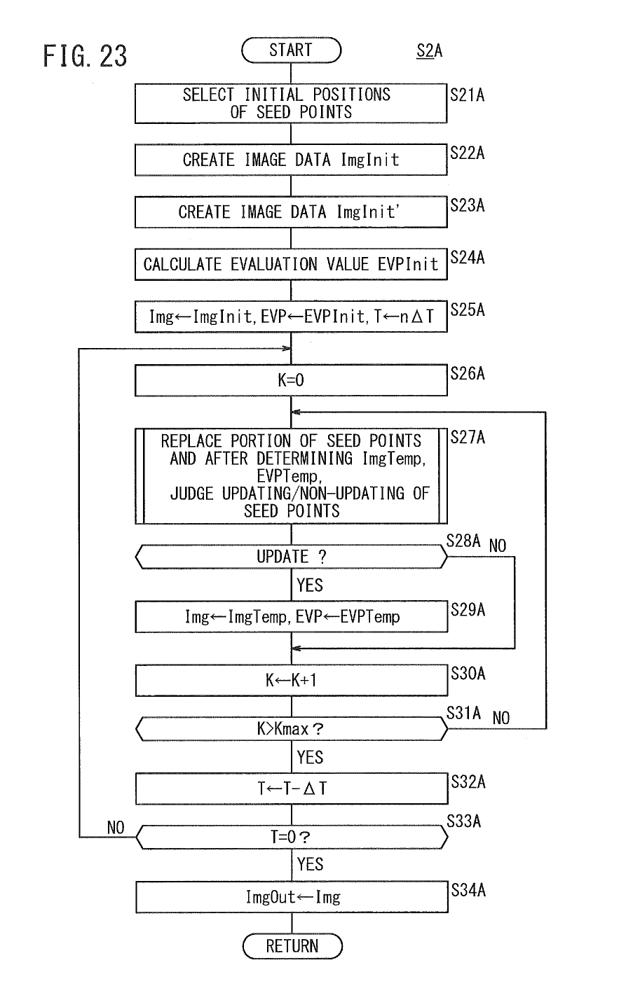

FIG. 23 is a flowchart providing a description of operations of an output image data creating method for creating output image data ImgOut according to the modified example of the present embodiment. Compared to FIG. 10, the present drawing differs in that a step (step S23A) is provided for creating the superimposed image data ImgInit′. The other steps S21A, S22A, S24A through S26A, and S28A through S34A correspond respectively to steps S21, S22, S23 through S25, and S27 through S33, and thus explanation of the operations of such steps is omitted.

In step S23A, the image data generating unit 40 generates superimposed image data ImgInit′ based on the image data ImgInit generated in step S22A and image information estimated by the image information estimating unit 38 (refer to the explanation of step S1). The superimposed image data ImgInit′ is image data representative of a pattern in which a black matrix 64 as a structural pattern is superimposed on the mesh pattern M.

In the case that the data definitions for pixel values of the image data ImgInit are indicative of transmission density, the transmission density (the value input to the text box 166 in FIG. 22) of each of the pixels is added corresponding to the arrangement position of the black matrix 64, and the superimposed image data ImgInit′ can be generated. Further, in the case that the data definitions for pixel values of the image data ImgInit are indicative of reflection density, the reflection density (the value input to the same text box 166) of each of the pixels is substituted therefor corresponding to the arrangement position of the black matrix 64, and the superimposed image data ImgInit′ can be generated.

In step S27A, in a condition in which a portion of the seed points SD (second seed points SDS) are replaced by candidate points SP, image data ImgTemp is generated, and after the evaluation value EVPTemp is calculated, a determination is made as to whether to “update” or “not update” the seed points SD.

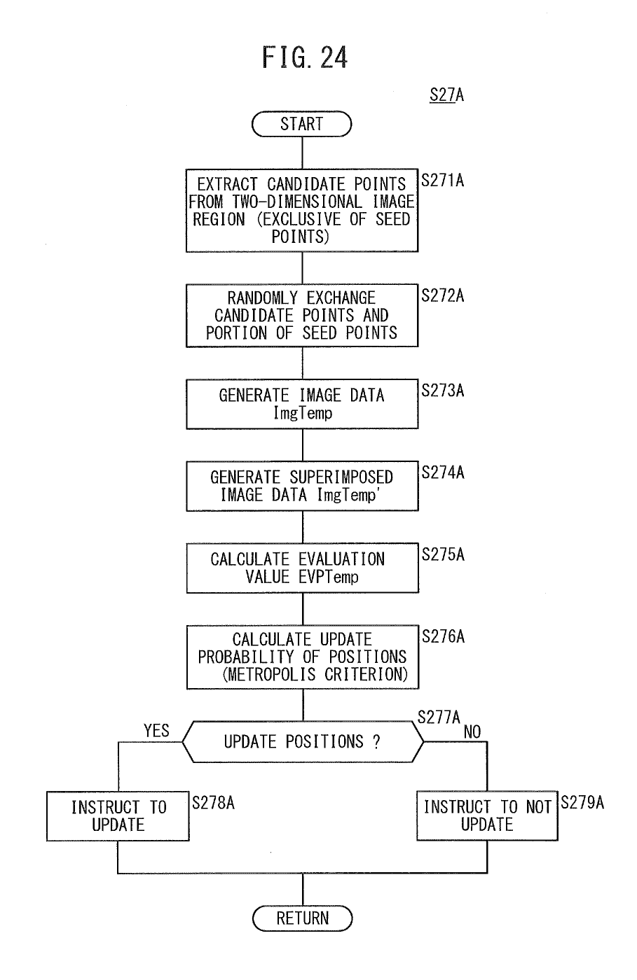

In comparison with FIG. 16, the flowchart of FIG. 24 in the present modified example differs in that a step (step S274A) is provided for generating superimposed image data ImgTemp′. Other steps S271A through S273A and 275A through 279A correspond respectively to steps S261 through S263 and steps S264 through S268 of FIG. 16.

In step S274A, the image data generating unit 40 generates superimposed image data ImgTemp′ based on the image data ImgTemp generated in step S273A and image information estimated by the image information estimating unit 38 (refer to the explanation of step S1). At this time, the method used is the same as in the case of step S23A (see FIG. 23) and thus explanations are omitted.

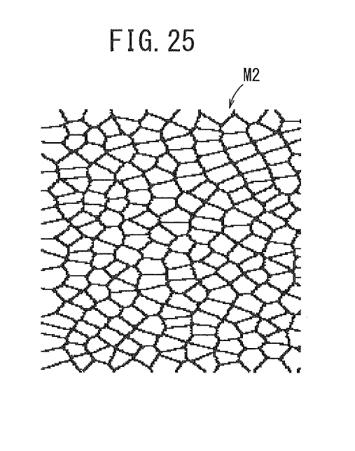

FIG. 25 is an outline explanatory view in which a mesh pattern M2 representing the pattern of the conductive sheet 14 is made visual using output image data ImgOut optimized under conditions of being superimposed with the black matrix 64.

As can be understood from FIGS. 20 and 25, compared to the pattern of the mesh pattern Ml, the pattern (each of the openings 52) of the mesh pattern M2 has a laterally elongate shape as a whole. The basis therefore is estimated in the following manner.

For example, the shape of the unit pixels 66 of the black matrix 64 shown in FIG. 2B is assumed to be square. By arranging the red filters 62r, green filters 62g, and blue filters 62b in a horizontal direction, the unit pixels 66 are partitioned into regions that are 1/3the size of the unit pixels 66, whereby noise granularity of high spatial frequency components increases. On the other hand, in the vertical direction, only spatial frequency components exist that correspond to the period at which the light-shielding materials 68h are disposed, and so that spatial frequency components apart therefrom do not exist, the pattern of the mesh pattern M2 is determined such that visibility of the arrangement period is low. In other words, respective wires that extend in the horizontal direction are determined so that intervals therebetween are as narrow as possible, and the wires are arranged regularly between the respective light-shielding materials 68h.

In this manner, by superimposing the black matrix 64 (structural pattern) and creating the image data Img (including output image data ImgOut), the mesh shape can be optimized taking into consideration the pattern of the black matrix 64. Stated otherwise, the sensation to granular noise observed under the manner of actual use is reduced, while the visibility of objects to be observed is significantly enhanced. This is particularly effective in cases where the actual manner of use of the conductive sheet 14 is known beforehand.

In the case that the actual manner of use of the conductive sheet 14 is not known beforehand, by optimizing the pattern of the mesh pattern Ml under a condition in which the presence of the structural pattern is not considered, an advantage also exists in that visibility of objects to be observed can be enhanced irrespective of the type of structural pattern that is superimposed thereafter. This is even more so in the event that a structural pattern is not superimposed.

Incidentally, using a method similar to that of the above-described embodiment, a conductive sheet 14 having the mesh pattern M2 (hereinafter referred to as a second sample) was manufactured. In the above (exposure pattern creating) process, the conditions for the black matrix 64 were set such that the optical density was 4.5 D, the unit pixel 66 had a vertical size and a horizontal size of 200 μm, and the widths of the light-shielding material 68v and the light-shielding material 68h were both 20 μm.

More specifically, the radio button 162a on the setting screen 160 (see FIG. 22) was selected, and with “PRESENCE/ABSENCE OF MATRIX” being set to “PRESENCE”, the output image data ImgOut was created. As a result, output image data ImgOut representing the pattern of the mesh pattern M2 (see FIG. 25) was obtained.

According to the aforementioned (noise sensation evaluation), it was confirmed that the second sample exhibited less noise than the first sample, i.e., the sensation to noise was not as conspicuous. Furthermore, using a transparent plate instead of the liquid crystal panel, light across the aforementioned LED lamp was observed, and a similar visual evaluation was carried out, whereby it was confirmed that in the case of the first sample, the sensation to noise was considerably less noticeable than in the case of the second sample. More specifically, it was appreciated that the pattern of the mesh pattern M could be optimized responsive to the visual aspects of the conductive sheet 14 (e.g., color filters such as the red filters 62r or the like, and presence or absence of the black matrix 64).

The present invention is not limited to the embodiment described above, but various changes and modifications may be made without departing from the scope of the invention.

For example, the pattern material is not limited to being a black matrix, and it goes without saying that, responsive to the various uses thereof, the present invention can be applied with respect to structural patterns of various shapes.

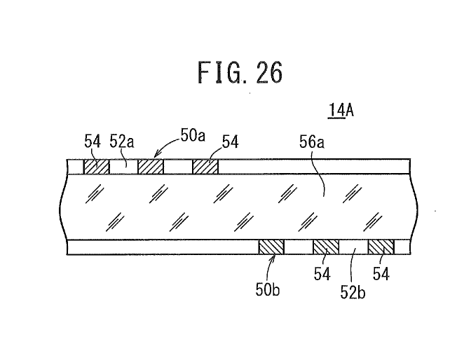

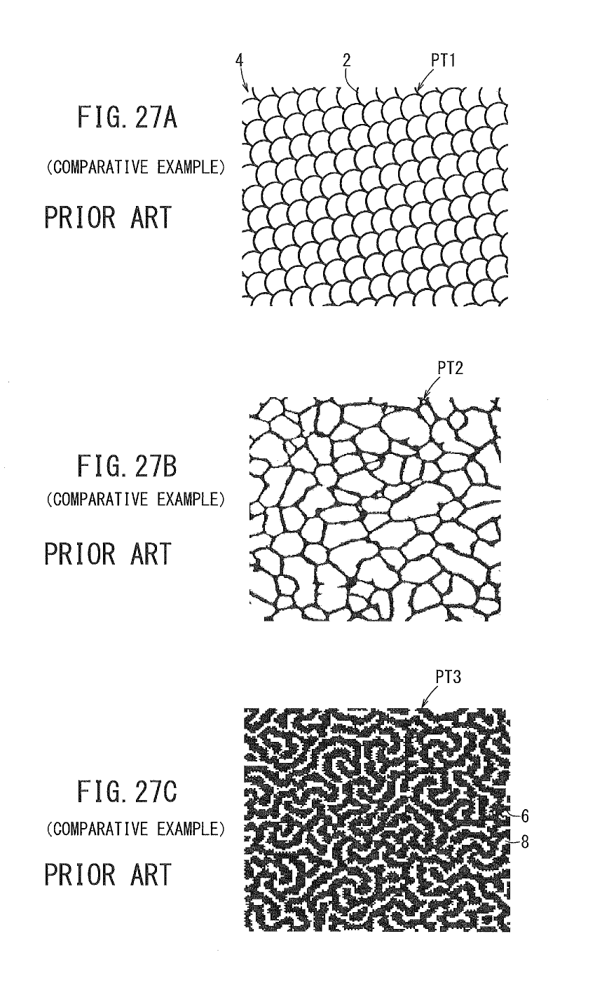

Further, the first conductive portions 50a and the second conductive portions 50b may be formed on a single substrate. For example, as shown in FIG. 26, the first conductive portions 50a may be formed on one principal surface of the first transparent substrate 56a, whereas the second conductive portions 50b may be formed on another principal surface of the first transparent substrate 56a. In this case, a form is provided in which the first transparent substrate 56a is stacked on the second conductive portions 50b without the presence of the second transparent substrate 56b, and the first conductive portions 50a are stacked on the first transparent substrate 56a. Further, another layer may exist between the first conductive sheet 14a and the second conductive sheet 14b, and if the first conductive portions 50a and the second conductive portions 50b are in an insulated condition, the first conductive portions 50a and the second conductive portions 50b may be arranged in confronting relation to each other.

Furthermore, the conductive sheet 14 is not limited to being used as an electrode for a touch panel, but may be applied to an electrode for an inorganic EL element, an organic EL element, or a solar cell, or may be used as a transparent heating element or an electromagnetic wave shielding member. For example, in the case that the conductive sheet 14 is applied to a defroster (defrosting device) of a vehicle, non-illustrated first and second electrodes are formed at opposite confronting end portions of the conductive sheet 14, and current is made to flow from the first electrode to the second electrode. Consequently, the transparent heating element generates heat, and the heat is applied to an object to be heated (for example, a building window glass, window glass for a vehicle, a front cover for a vehicle lamp, etc.) which is placed in contact with or incorporates therein the transparent heating element. As a result, snow or the like that adheres to the object to be heated can be removed.

1. A method of manufacturing a conductive sheet comprising:
a generating step of generating image data representing the pattern of a mesh pattern; and
an outputting step of outputting and forming a wire material on a substrate based on the generated image data to thereby manufacture the conductive sheet having the mesh pattern,
wherein the image data has a characteristic such that, in a convolution integral between a power spectrum of the image data and a standard human visual response characteristic, respective integral values, which reside within a spatial frequency band greater than or equal to 1/4 of and less than or equal to 1/2 of a Nyquist frequency corresponding to the image data, are greater than an integral value thereof at zero spatial frequency.

2. The method of manufacturing a conductive sheet according to claim 1, further comprising:
a cutout step of cutting out, respectively, from a predetermined two-dimensional image region in which the pattern of the mesh pattern is formed, a first image region that defines a periodically arranged geometric pattern, and a second image region that includes at least a remaining area of the first image region within the predetermined two-dimensional image region, wherein:
in the generating step, first image data corresponding to the first image region that was cut out, and second image data corresponding to the second image region that was cut out are generated; and
in the outputting step, by outputting and forming the wire material based on the first image data and the second image data that were generated, the pattern of the mesh pattern is made up on the substrate.

3. The method of manufacturing a conductive sheet according to claim 1, wherein:
the image data includes a plurality of color channels; and
the integral value is a weighted sum of each of the color channels.

4. The method of manufacturing a conductive sheet according to claim 1, further comprising:
a selection step of selecting a plurality of positions from within a predetermined two-dimensional image region,
wherein, in the generating step, the image data is generated based on the selected plurality of positions.

5. The method of manufacturing a conductive sheet according to claim 1, wherein the standard human visual response characteristic is obtained based on a Dooley-Shaw function at an observational distance of 300 mm.

6. A conductive sheet which is manufactured using the manufacturing method according to claim 1.

7. A method of manufacturing a conductive sheet comprising:
a generating step for generating image data representing the pattern of a mesh pattern, based on an evaluation result of superimposed image data obtained by superimposing the mesh pattern on a structural pattern having a pattern different from the pattern of the mesh pattern; and
an outputting step of outputting and forming a wire material on a substrate based on the generated image data to thereby manufacture the conductive sheet having the mesh pattern,
wherein the superimposed image data has a characteristic such that, in a convolution integral between a power spectrum of the superimposed image data and a standard human visual response characteristic, respective integral values, which reside within a spatial frequency band greater than or equal to 1/4 of and less than or equal to 1/2 of a Nyquist frequency corresponding to the superimposed image data, are greater than an integral value thereof at zero spatial frequency.

8. The method of manufacturing a conductive sheet according to claim 7, wherein the structural pattern comprises a black matrix.

9. The method of manufacturing a conductive sheet according to claim 7, further comprising:
a cutout step of cutting out, respectively, from a predetermined two-dimensional image region in which the pattern of the mesh pattern is formed, a first image region that defines a periodically arranged geometric pattern, and a second image region that includes at least a remaining area of the first image region within the predetermined two-dimensional image region, wherein:
in the generating step, first image data corresponding to the first image region that was cut out, and second image data corresponding to the second image region that was cut out are generated; and
in the outputting step, by outputting and forming the wire material based on the first image data and the second image data that were generated, the pattern of the mesh pattern is made up on the substrate.

10. The method of manufacturing a conductive sheet according to claim 7, wherein:
the image data includes a plurality of color channels; and
the integral value is a weighted sum of each of the color channels.

11. The method of manufacturing a conductive sheet according to claim 7, further comprising:
a selection step of selecting a plurality of positions from within a predetermined two-dimensional image region,
wherein, in the generating step, the image data is generated based on the selected plurality of positions.

12. The method of manufacturing a conductive sheet according to claim 7, wherein the standard human visual response characteristic is obtained based on a Dooley-Shaw function at an observational distance of 300 mm.

13. A conductive sheet which is manufactured using the manufacturing method according to claim 7.

14. A conductive sheet in which a wire material in the form of a mesh pattern is formed on a substrate, wherein, in a convolution integral between a power spectrum as viewed in plan and a standard human visual response characteristic, respective integral values, which reside within a spatial frequency band greater than or equal to 1/4 of and less than or equal to 1/2 of a spatial frequency corresponding to an average line width of the wire material, are greater than an integral value thereof at zero spatial frequency.

15. A conductive sheet in which a wire material in the form of a mesh pattern is formed on a substrate,
wherein, under a condition in which a structural pattern having a pattern different from the mesh pattern is superimposed on the conductive sheet, in a convolution integral between a power spectrum as viewed in plan and a standard human visual response characteristic, respective integral values, which reside within a spatial frequency band greater than or equal to 1/4 of and less than or equal to 1/2 of a spatial frequency corresponding to an average line width of the wire material, are greater than an integral value thereof at zero spatial frequency.

16. A recording medium storing therein a program for creating image data representing the pattern of a mesh pattern, wherein the program enables the computer to function as:
an input device for inputting visual information in relation to visibility of a mesh pattern; and
an image data generating unit for generating the image data that satisfies predetermined spatial frequency conditions, based on the visual information input from the input device,
wherein the predetermined spatial frequency conditions are such that, in a convolution integral between a power spectrum of the image data and a standard human visual response characteristic, respective integral values, which reside within a spatial frequency band greater than or equal to 1/4 of and less than or equal to 1/2 of a Nyquist frequency corresponding to the image data, are greater than an integral value thereof at zero spatial frequency.
